(19) United States
(12) Patent Application Publication
(10) Pub. No.: US 2025/0209242 A1
(43) Pub. Date: Jun. 26, 2025

(54) INFORMATION PROCESSING DEVICE AND INFORMATION PROCESSING METHOD

(71) Applicant: Mitsubishi Electric Corporation, Tokyo (JP)

(72) Inventors: Yusuke YAMAKAJI, Tokyo (JP); Kenji HIROSE, Tokyo (JP); Kunihiko FUKUSHIMA, Tokyo (JP)

(73) Assignee: Mitsubishi Electric Corporation, Tokyo (JP)

(21) Appl. No.: 19/079,157

(22) Filed: Mar. 13, 2025

Related U.S. Application Data
(63) Continuation of application No. PCT/JP2022/039214, filed on Oct. 21, 2022.

(51) Int. Cl. G06F 30/32; G06F 30/12

(52) U.S. Cl. CPC G06F 30/32; G06F 30/12

(57) ABSTRACT

An information processing device includes an acquisition unit to acquire a netlist of an electric circuit, and a processing unit to extract a component name list and a wiring name list from the netlist, and create a component name list that is updated by adding component names indicating a ground terminal, an input terminal, and an output terminal, a wiring name list that is updated by removing wiring names indicating a ground wiring, an input wiring, and an output wiring, and a combination list including an extracted component name obtained by extracting a component name corresponding to a wiring name in the updated wiring name list from the component names in the updated component name list, and output the updated component name list and the combination list.

### CROSS REFERENCE TO RELATED APPLICATIONS

This application is a Continuation of PCT International Application No. PCT/JP2022/039214 filed on Oct. 21, 2022, all of which is hereby expressly incorporated by reference into the present application.

### TECHNICAL FIELD

The present disclosure relates to an information processing device and an information processing method.

### BACKGROUND ART

Circuit diagram data indicating an electric circuit designed using computer-aided design (CAD) is data including component information regarding components and connection information regarding wiring between the components. For example, Patent Literature 1 describes a technique of searching for circuit diagram data of electric circuits having similar configurations from a database in which circuit diagram data is registered, using a circuit matrix in which the electric circuits are represented by a matrix.

### CITATION LIST

### Patent Literatures

Patent Literature 1: JP 2007-128383 A

### SUMMARY OF INVENTION

### Technical Problem

A graph network representing an electric circuit by nodes and edges is created using list information extracted from a netlist of electric circuits. The list information is information regarding components and wirings included in the electric circuit, and includes a component name list and a wiring name list. In the component name list, component names of components included in the electric circuit are set. In the wiring name list, wiring names of wirings connecting components are set.

The wirings whose wiring names are set in the wiring name list includes ground wirings, input wirings, and output wirings in the electric circuit. On the other hand, in the component name list, only component names of circuit components having structural features are set, and elements indicating grounds, inputs, and outputs that do not have structural features are not included. Accordingly, in the conventional list information, it is necessary to define various types of grounds, a plurality of inputs, and a plurality of outputs by wiring.

On the other hand, in the conventional list information, when the circuit has a unique ground or a unique input and output, unless a special mechanism is provided for each circuit, the ground or the input and output cannot be distinguished as different circuit information. For example, an input of a circuit component includes a power supply to the circuit component, and also includes an input of an external signal. As described above, there are various inputs of circuit components, and definition only by wiring names causes confusion of both. Thus, it is difficult to separate both only by the graph network after the electric circuit is converted into the graph network.

In order to separate the both, it is necessary to have specifications of the number of components or the order of description on the graph network, and it is usable only when the number of input terminals is determined in advance. In a case where the graph network is created without the above specifications by using list information in which definitions of ground, input, and output in circuit components are not appropriate, information deterioration may occur in the graph network. When information deterioration occurs, the original circuit diagram may not be restored from the graph network.

By the way, in the conventional technique described in Patent Literature 1, when a circuit matrix is created using list information in which definitions of ground, input, and output are not appropriate, information deterioration is expected to occur in the circuit matrix as described above. In this case, even if the circuit matrix is used, there is a possibility that circuit diagram data of similar electric circuits cannot be accurately searched.

The present disclosure solves the above problem, and the object of the present disclosure is to provide an information processing device and an information processing method capable of providing list information in which information deterioration caused by converting an electric circuit into a graph network can be suppressed.

### Solution to Problem

An information processing device according to the present disclosure includes a processor; and a memory storing a program, upon executed by the processor, to perform a process: to acquire a netlist of an electric circuit; and to extract a component name list and a wiring name list from the netlist, and create a component name list that is updated by adding component names indicating a ground terminal, an input terminal, and an output terminal, a wiring name list that is updated by removing wiring names indicating a ground wiring, an input wiring, and an output wiring, and a combination list including an extracted component name obtained by extracting a component name corresponding to a wiring name in the updated wiring name list from the component names in the updated component name list, and output the updated component name list and the combination list.

### Advantageous Effects of Invention

According to the present disclosure, a component name list and a wiring name list are extracted from the netlist of an electric circuit, and there are created a component name list that is updated by adding component names indicating a ground terminal, an input terminal, and an output terminal, a wiring name list that is updated by removing wiring names indicating a ground wiring, an input wiring, and an output wiring, and a combination list including an extracted component name obtained by extracting a component name corresponding to a wiring name in the updated wiring name list from the component names in the updated component name list, and the updated component name list and the combination list are output. In this manner, the information processing device according to the present disclosure outputs the list information in which the ground, the input, and the output in the electric circuit are defined as circuit components, so that it is possible to provide the list information in which information deterioration caused by converting the electric circuit into the graph network can be suppressed.

### BRIEF DESCRIPTION OF DRAWINGS

FIG. 1 is a block diagram illustrating a configuration example of an information processing device according to a first embodiment.

FIG. 2 is a schematic diagram illustrating an example (1) of an electric circuit and a graph network according to the first embodiment.

FIG. 3 is a schematic diagram illustrating an example (2) of the electric circuit and the graph network according to the first embodiment.

FIGS. 4A and 4B are block diagrams illustrating a hardware configuration that implements functions of the information processing device according to the first embodiment.

FIG. 5 is a flowchart illustrating an information processing method according to the first embodiment.

FIG. 6 is a circuit diagram illustrating an example (1) of an electric circuit.

FIG. 7 is a circuit diagram illustrating an example (2) of an electric circuit.

FIG. 8 is a circuit diagram illustrating an example (3) of an electric circuit.

FIG. 9 is a schematic diagram illustrating a graph network in which nodes are connected by edges.

FIG. 10 is a schematic diagram illustrating a graph network in which nodes are connected via wiring nodes.

FIG. 11 is a flowchart illustrating data input processing (1) to the graph network in the first embodiment.

FIG. 12 is a flowchart illustrating data input processing (2) to the graph network in the first embodiment.

FIG. 13 is a flowchart illustrating data input processing (3) to the graph network in the first embodiment.

FIG. 14 is a graph illustrating an example (1) of a calculation result of inference accuracy by the information processing device according to the first embodiment.

FIG. 15 is a graph illustrating an example (2) of a calculation result of inference accuracy by the information processing device according to the first embodiment.

FIG. 16 is a block diagram illustrating a configuration example of an information processing device according to a second embodiment.

FIG. 17 is a flowchart illustrating an information processing method according to the second embodiment.

FIG. 18 is a circuit diagram illustrating an example (4) of an electric circuit.

FIG. 19 is a circuit diagram illustrating an example (5) of an electric circuit.

FIG. 20 is a schematic diagram illustrating an example (1) of an electric circuit and a graph network according to the second embodiment.

FIG. 21 is a schematic diagram illustrating an example (2) of an electric circuit and a graph network according to the second embodiment.

FIG. 22 is a schematic diagram illustrating an example (3) of an electric circuit and a graph network according to the second embodiment.

FIG. 23 is a graph illustrating an example of a calculation result of inference accuracy by the information processing device according to the second embodiment.

### DESCRIPTION OF EMBODIMENTS

### First Embodiment

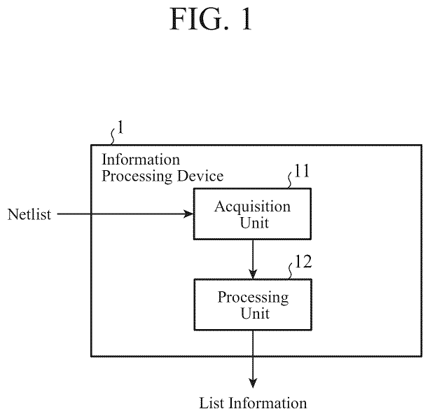

FIG. 1 is a block diagram illustrating a configuration example of an information processing device 1 according to a first embodiment. In FIG. 1, an information processing device 1 acquires a netlist of an electric circuit, and provides list information in which information deterioration in a graph network of the electric circuit can be suppressed by using the acquired netlist can be suppressed. The graph network of the electric circuit is information representing the electric circuit using a node representing a component and an edge representing a wiring line. The graph network also includes information indicating a feature amount of the node and a feature amount of the edge.

In creating an electric circuit, a circuit diagram of the electric circuit is designed using a circuit design CAD, information indicating the circuit diagram is passed to a board design CAD, and a board circuit pattern is designed using the board design CAD. The information indicating the circuit diagram passed from the circuit design CAD to the board design CAD is the netlist of the electric circuit. For example, the information processing device 1 acquires the netlist from the circuit design CAD, and outputs the netlist including list information created using the acquired netlist to a computer on which the board design CAD is mounted. In the computer, a board circuit pattern for the circuit diagram indicated by the input netlist is designed using the board design CAD.

The circuit diagram indicated by the netlist includes information indicating a passive component, an active component, an I/O component, and a wiring in the electric circuit. The passive component is a component such as a coil, a capacitor, a resistor, or a diode. The active component is a component such as a power supply, a processor, a memory, or a field programmable gate array (FPGA). The I/O component is, for example, an inter-board connector, a power supply connector, and a communication connector. The wiring is a wiring for connecting the above components.

The power supply itself is not included in the circuit diagram because the circuit diagram illustrates an electric circuit that operates when power is supplied from the outside or when a control signal of Ethernet (registered trademark) or the like or an analog signal acquired from a sensor is input. The power supply is a battery or a commercial power source.

Note that, hereinafter, it is assumed that at least a ground wiring, an input wiring, and an output wiring are connected to one or more circuit components in the circuit diagram. In addition, the circuit diagram indicated by the netlist does not necessarily need to operate, and may be in the middle of design, or may be obtained by extracting only a circuit portion that implements some functions of the entire circuit.

Although several tens of types of expression methods such as the TELESIS format, the PADS format, and the SCICARDS format are known in the netlist, any format includes information indicating components included in the electric circuit and wiring connecting the components. Generally, the circuit diagram includes a ground wiring, an input wiring, and an output wiring. However, there may be no input wiring or output wiring in a circuit diagram that handles electromagnetic waves, heat, or the like input or output without wiring. Note that, in a case where an electromagnetic wave or heat is converted into an electric signal and an electric signal is converted into an electromagnetic wave or heat, the circuit diagram includes an input wiring through which the electric signal converted from the electromagnetic wave or heat propagates, and includes an output signal through which the electric signal to be converted into an electromagnetic wave or heat propagates. The netlist also includes information regarding such wiring.

Further, the netlist includes a component name list and a wiring name list. In the component name list, all component names in the netlist are set. In the wiring name list, all wiring names in the netlist are set. In the wiring name list, wiring names indicating a ground wiring, an input wiring, and an output wiring in the electric circuit are also set, but in the component name list, information indicating a ground, an input, and an output is not set, and only a circuit component having a structural feature such as a semiconductor element (hereinafter, simply referred to as a semiconductor) or a capacitor is set. Thus, even when there is a plurality of types of grounds, inputs, and outputs in the electric circuit, these cannot be distinguished from the component name list.

In this case, in the wiring name list, it is necessary to further classify and define the ground wiring, the input wiring, and the output wiring corresponding to the type of the ground, the input, and the output. For example, when there is a plurality of types of ground, input, and output in a certain component, it is necessary to define a plurality of types of wirings classified corresponding to the types of ground, input, and output also between this component and a component to be connected, and a wiring name list becomes complicated. When an electric circuit is converted into a graph network using list information, including a complicated wiring name list, there is a high possibility that information deterioration occurs in the graph network.

On the other hand, the information processing device 1 adds component names indicating a ground terminal, an input terminal, and an output terminal to the component name list, and removes the wiring names indicating the ground wiring, the input wiring, and the output wiring from the wiring name list. Then, the information processing device 1 extracts a component name corresponding to the wiring name in the wiring name list from the component names in the component name list, creates a combination list including the extracted component name, and outputs list information including the component name list and the combination list. In this manner, in the information processing device 1, even if there is a plurality of types of grounds, inputs, and outputs in the electric circuit, these can be defined as individual components. Thus, it is possible to provide list information in which information deterioration in the graph network of the electric circuit can be suppressed without complicating the list information as in the case of defining a plurality of types of wirings.

As illustrated in FIG. 1, the information processing device 1 includes an acquisition unit 11 and a processing unit 12.

The acquisition unit 11 executes a first process of acquiring a netlist of the electric circuit. For example, the information processing device 1 is connected to a computer equipped with circuit design CAD, and the acquisition unit 11 acquires a netlist created using the circuit design CAD from the computer.

In addition, the acquisition unit 11 may acquire a circuit diagram model of an electric circuit operating in a circuit simulator and convert the circuit diagram indicated by the circuit diagram model into a netlist.

That is, the acquisition of the netlist by the acquisition unit 11 includes acquiring the netlist by converting the circuit diagram.

The processing unit 12 extracts the component name list and the wiring name list from the netlist, and creates a component name list that is updated by adding component names indicating a ground terminal, an input terminal, and an output terminal, a wiring name list that is updated by removing wiring names indicating a ground wiring, an input wiring, and an output wiring, and a combination list including an extracted component name obtained by extracting a component name corresponding to a wiring name in the updated wiring name list from the component names in the updated component name list, and outputs the updated component name list and the combination list. In addition, the processing unit 12 outputs the updated component name list and the combination list in which a component name is replaced with a unique identification number common to each of features of components.

Specifically, the processing unit 12 executes a second process to a sixth process.

The second process is a process of extracting the component name list and the wiring name list from the netlist acquired by the acquisition unit 11.

The third process is a process of adding component names indicating a ground terminal, an input terminal, and an output terminal to the component name list.

The fourth process is a process of removing wiring names indicating ground wirings, input wirings, and output wirings from the wiring name list.

The fifth process is a process of extracting a component name corresponding to a wiring name in the wiring name list subjected to the fourth process from the component names in the component name list subjected to the third process, and creating a combination list including the extracted component name.

The sixth process is a process of replacing the component name in the component name list subjected to the third process with the component name in the combination list obtained in the fifth process with a unique identification number common to each of the features of the component, and outputting list information including the component name list and the combination list in which the component name is replaced with the identification number.

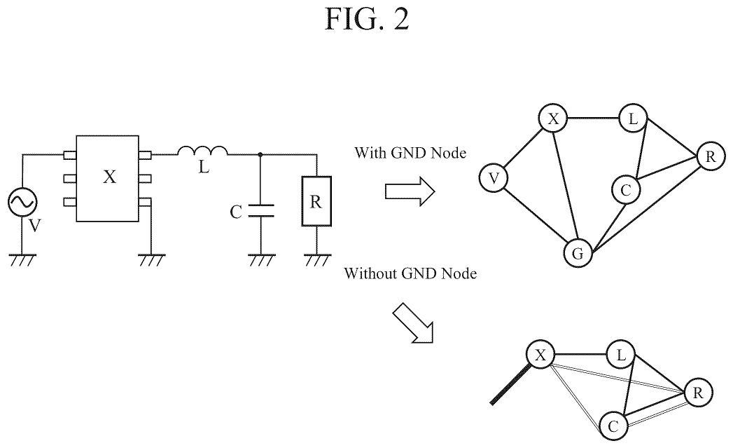

FIG. 2 is a schematic diagram illustrating an example (1) of an electric circuit and a graph network, in which the left diagram of FIG. 2 illustrates an example of an electric circuit, and the upper and lower diagrams on the right side illustrate a graph network of the electric circuit on the left side. The electric circuit illustrated in FIG. 2 is a circuit including a power supply V, a semiconductor X, an inductor L, a capacitor C, and a resistor R. In the electric circuit, the power supply V, one terminal of the semiconductor X, the capacitor C, and the resistor R are connected to a ground GND.

The power supply V itself is not included in a circuit diagram of an electric circuit that operates by electric power supplied (input) from the power supply V. Thus, in a netlist representing the circuit diagram, an input terminal to which electric power is supplied from the power supply is not set as a circuit component. In addition, in the component name list included in the netlist, electric circuit components such as the semiconductor X, the inductor L, the capacitor C, and the resistor R having a functional structure are set, but a power input or a ground GND not having a functional structure is not set.

When the component name list in which the power input and the ground GND are not set is used, the graph network on the lower right side is created. In the graph network on the lower right side, there is a node of the semiconductor X, a node of the inductor L, a node of the capacitor C, and a node of the resistor R, but there is no node of a power input from the power supply V and no node of the ground GND. In the graph network on the lower right side, the power input from the power supply V and the ground GND are defined as wirings.

For example, in the electric circuit on the left side, power is supplied (input) from the power supply V to one terminal of the semiconductor X. Thus, in the graph network on the lower right side, the thick line wiring connected to the node of the semiconductor X is an input wiring related to the power input from the power supply V.

In addition, in the electric circuit on the left side, the semiconductor X, the capacitor C, and the resistor R are connected to the ground GND.

For example, as indicated by white lines, the ground GND is defined as a ground wiring between the semiconductor X and the capacitor C, a ground wiring between the semiconductor X and the resistor R, and a ground wiring between the capacitor C and the resistor R. That is, when the power input and the ground GND are not set in the component name list, four types of wirings indicating the power input from the power supply V and the ground GND are defined in the netlist.

When the original electric circuit can be specified using the netlist obtained by inversely converting the converted graph network into the netlist after converting the netlist of the electric circuit into the graph network, it is determined that there is no information deterioration in the graph network.

In general, there is no reversibility between the conversion from the netlist to the graph network and the inverse conversion from the graph network to the netlist, and the netlist after the inverse conversion may not be a netlist that can be calculated by the circuit simulator.

Thus, information deterioration of the graph network is determined by inputting the graph network to the graph neural network and training the graph neural network for inferring the original electric circuit without performing inverse conversion from the graph network to the netlist. In the determination of information deterioration using the graph neural network, the process of inversely converting the netlist from the graph network is not performed, so that there is an effect that the above problem does not occur. However, the graph neural network has a problem of variation in inference results. In this case, it is possible to suppress the influence of the variation in inference results to be small by training of the graph neural network having a common network structure a plurality of times and confirming the variation in inference results by the graph neural network of the trained model.

As described above, the determination of information deterioration using the graph neural network is an excellent determination method that can obtain a more stable result than in a case where inverse conversion from the graph network to the netlist is performed.

Here, the graph neural network is a machine learning model (AI) that infers an electric circuit corresponding to a graph network when the graph network is input.

If the graph neural network has a high accuracy of inferring the original electric circuit, it is determined that there is small information deterioration that occurs when the netlist of the electric circuit is converted into the graph network.

In a case where there is a plurality of types of ground GNDs, inputs, and outputs in an electric circuit, in a graph network obtained by converting a netlist of the electric circuit, the ground GNDs, and wirings indicating the inputs and the outputs are classified and defined corresponding to the types of the ground GNDs, the inputs, and the outputs. These wirings are defined under complicated conditions including a relationship with a connected component in addition to information indicating a classified type. Thus, the graph neural network needs to train, including a complicated condition for each wiring, and inference accuracy with which the graph neural network infers the original electric circuit decreases.

On the other hand, the information processing device 1 adds component names indicating the ground terminal, the input terminal, and the output terminal to the component name list included in the netlist of the electric circuit on the left side, and removes the wiring names indicating the ground wiring, the input wiring, and the output wiring from the wiring name list included in the netlist. Then, the information processing device 1 extracts a component name corresponding to the wiring name in the wiring name list from the component names in the component name list, creates a combination list including the extracted component name, and outputs the component name list and the combination list.

In the component name list and the combination list, the power input of the power supply V and the ground GND in the electric circuit on the left side are set as components. Thus, the netlist including the component name list and the combination list is converted into the graph network on the upper right side. In the graph network on the upper right side, in addition to the node of the semiconductor X, the node of the inductor L, the node of the capacitor C, and the node of the resistor R, a node of a power input from the power supply V and a node of the ground GND are set.

Since the power input from the power supply V and the ground GND are defined as components, in the graph network on the upper right side, the wiring related to the power input from the power supply V to the semiconductor X does not need to be classified into types of input wiring, and is defined as a connection between nodes.

The ground GND also does not need to be classified into types of ground wiring, and is defined as a connection between nodes. That is, in the graph network on the upper right side, all the wirings in the original electric circuit are defined by one type of wiring connecting nodes.

Thus, a plurality of types of ground GNDs, inputs, and outputs included in the electric circuit are distinguished as components. That is, the graph neural network can train the ground GNDs, the inputs, and the outputs in the electric circuit as components, and accuracy with which the graph neural network infers the original electric circuit is improved.

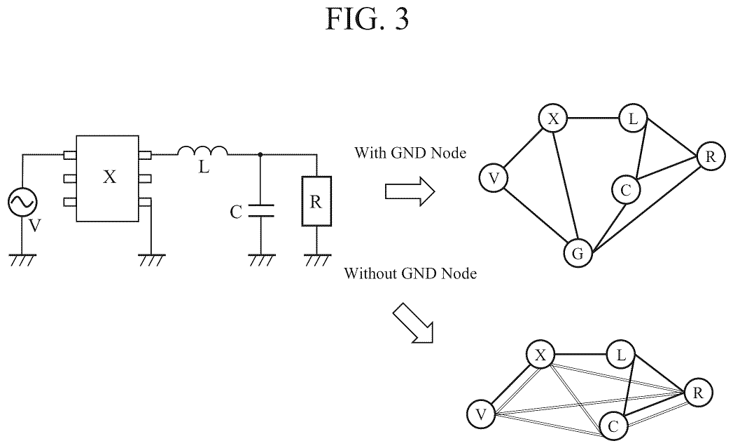

FIG. 3 is a schematic diagram illustrating an example (2) of an electric circuit and a graph network, in which a left diagram of FIG. 3 illustrates an example of an electric circuit, and both the upper and lower diagrams on the right side illustrate a graph network of the electric circuit on the left side. The electric circuit illustrated in FIG. 3 is a circuit including a power supply V, a semiconductor X, an inductor L, a capacitor C, and a resistor R. When the component name list in which the ground GND is not set in the electric circuit on the left side is used, the electric circuit is converted into the graph network on the lower right side.

In the graph network on the lower right side, a power input node from the power supply V, a node of the semiconductor X, a node of the inductor L, a node of the capacitor C, and a node of the resistor R are set, and the ground GND is defined as a ground wiring set between nodes as indicated by a white line. In general, since there are many components connected to the ground GND among the components included in the electric circuit, it is necessary to define an enormous number of ground wirings for the ground GND depending on the circuit scale. Further, an output node is a voltage across the resistor R.

In the circuit diagram illustrated in FIG. 3 this time, the power supply V serving as an input node and the resistor R meaning a load of an output node are described for simplicity of description, but in a regular circuit diagram in electric design, the power supply V or the resistor R is not described and is expressed as an open end.

In addition, in the graph network on the lower right side, six ground wirings are set for the ground GND, but five more wirings for connecting nodes other than the ground GND are set. That is, it is necessary to define a total of 11 wirings in the netlist.

On the other hand, the information processing device 1 provides list information in which the ground GND is set as a component. This list information can be converted into a graph network on the upper right side. In the graph network on the upper right side, as illustrated in FIG. 3, a node of the ground GND is set in addition to the power input node from the power supply V, the node of the semiconductor X, the node of the inductor L, the node of the capacitor C, and the node of the resistor R.

Note that the semiconductor includes not only a single-function semiconductor such as a transistor, a diode, a metal-oxide-semiconductor field-effect transistor (MOSFET), or an insulated gate bipolar transistor (IGBT), but also a large-scale integrated circuit such as an IC or an LSI, for example, a CPU, a GPU, a memory, or an ASIC.

In the first embodiment, since a node can be defined including a large-scale integrated circuit in which an internal circuit element is unknown (black box), all semiconductors can be handled in a similar manner. Even in a case where an internal circuit element is known, in a circuit that handles a signal of a band other than a high frequency or a frequency targeted by a semiconductor, a result of circuit calculation often does not match with an actual measurement due to an influence of parasitic capacitance, residual inductance, residual resistance, or the like, that is, the circuit is not an equivalent circuit. Thus, even if an internal circuit element can be specified, it is often useless, and the present embodiment that can be treated as a black box has a special effect.

However, even when a circuit element inside an integrated circuit is unknown, attribute information of the integrated circuit itself such as a CPU or a memory can be grasped in many cases, and thus it is desirable to input the attribute information of the integrated circuit as attribute information of the semiconductor node.

Note that the attribute information is, for example, information obtained by combining various types of information described in specifications (also referred to as a specification sheet) such as a manufacturer, a type of a component, a model number of the component, a product lot, the number of terminals of the component, a frequency of an input signal to the component, a voltage of the input signal, a current of the input signal, power of the input signal, a frequency of an output signal from the component, a voltage of the output signal, a current of the output signal, and power or a dimension of the output signal.

By defining the ground GND as a component, in the graph network on the upper right side, it is sufficient if nine wirings connecting nine nodes are set. Thus, only a total of nine wirings need to be defined in the netlist, and the number of wirings to be defined in the netlist can be reduced as compared with a case where the ground GND is not defined as a component. By reducing the number of wirings, the amount of calculation can be reduced, and even a computer or edge computing that does not have high calculation performance can handle a large-scale circuit.

Next, a hardware configuration for implementing the functions of the information processing device 1 will be described.

The information processing device 1 is, for example, a computer connected to an information network.

The computer may be a server or client that can be connected to a cloud or the like via an information network, or may be a stand-alone computer that is not connected to the information network. It may also be a computer used in a closed network environment in a factory called edge computing.

Further, the information processing device 1 may be a smartphone, a tablet terminal, a personal computer (PC), or a microcomputer.

The information processing device 1 may be a device that uses an information processing service provided in the form of software as a service (SaaS). That is, a dedicated application for providing the information processing service in the first embodiment is executed by the server to which the information processing device 1 is connected via the information network, and the information processing device 1 can receive the provision of the information processing service on the web browser without installing the dedicated application.

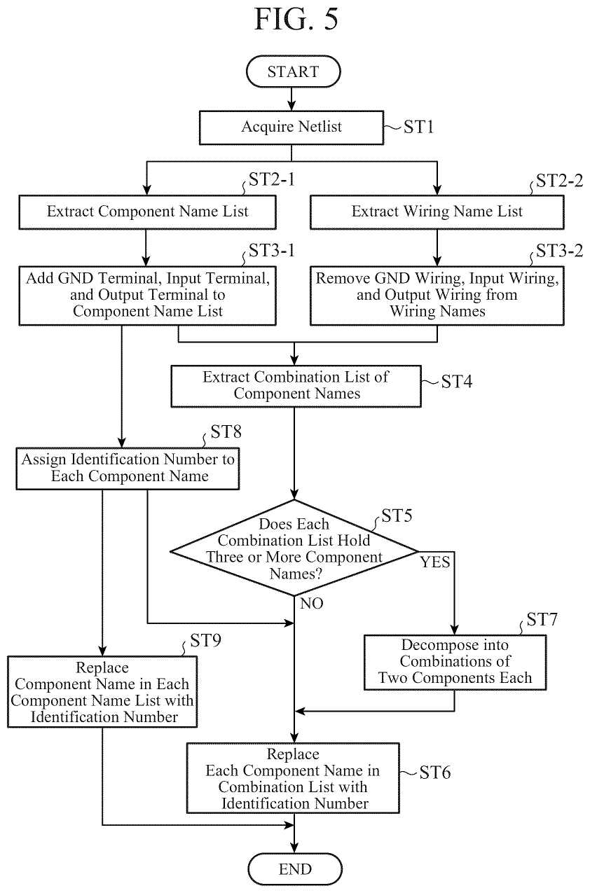

The functions of the acquisition unit 11 and the processing unit 12 included in the information processing device 1 are implemented by a processing circuit. That is, the information processing device 1 includes a processing circuit for executing processing of steps ST1 to ST9 illustrated in FIG. 5 to be described later. The processing circuit may be dedicated hardware, or may be a central processing unit (CPU) that executes a program stored in a memory.

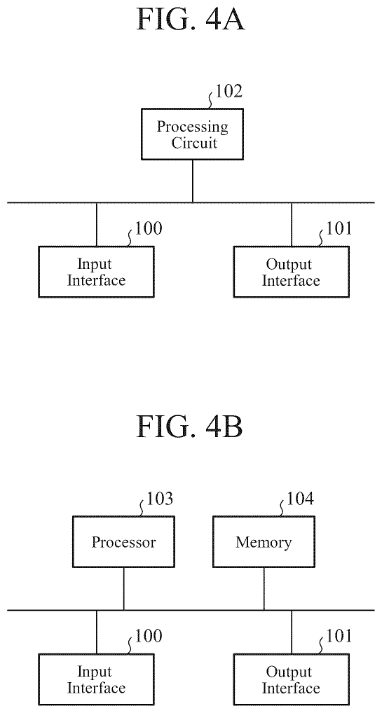

FIG. 4A is a block diagram illustrating hardware components that implement the functions of the information processing device 1. In FIG. 4A, an input interface 100, an output interface 101, and a processing circuit 102 are connected to each other via a bus wiring. In addition, FIG. 4B is a block diagram illustrating a hardware configuration for executing software for implementing the functions of the information processing device 1. In FIG. 4B, the input interface 100, the output interface 101, a processor 103, and a memory 104 are connected to each other via a bus wiring. In FIGS. 4A and 4B, the input interface 100 is, for example, an interface that relays the netlist acquired by the information processing device 1. The output interface 101 is an interface that relays list information output from the information processing device 1 to an external device.

In a case where the processing circuit is the processing circuit 102 of dedicated hardware illustrated in FIG. 4A, the processing circuit 102 corresponds to, for example, a single circuit, a composite circuit, a programmed processor, a parallel programmed processor, an application specific integrated circuit (ASIC), a field-programmable gate array (FPGA), or a combination thereof.

The functions of the acquisition unit 11 and the processing unit 12 included in the information processing device 1 may be implemented by separate processing circuits, or these functions may be collectively implemented by one processing circuit.

In a case where the processing circuit is the processor 103 illustrated in FIG. 4B, the functions of the acquisition unit 11 and the processing unit 12 included in the information processing device 1 are implemented by software, firmware, or a combination of software and firmware. Note that the software or firmware is described as a program and stored in the memory 104.

The processor 103 reads and executes the program stored in the memory 104, thereby implementing the functions of the acquisition unit 11 and the processing unit 12 included in the information processing device 1.

For example, the information processing device 1 includes the memory 104 for storing a program that, when executed by the processor 103, results in the execution of the processing of steps ST1 to ST9 illustrated in FIG. 5. These programs cause a computer to execute procedures or methods of processing performed by the acquisition unit 11 and the processing unit 12. The memory 104 may be a computer-readable storage medium storing a program for causing a computer to function as the acquisition unit 11 and the processing unit 12.

The memory 104 corresponds to a nonvolatile or volatile semiconductor memory such as a random-access memory (RAM), a read-only memory (ROM), a flash memory, an erasable programmable read-only memory (EPROM), or an electrically-EPROM (EEPROM), a magnetic disk, a flexible disk, an optical disk, a compact disk, a mini disk, or a DVD.

A part of the functions of the acquisition unit 11 and the processing unit 12 included in the information processing device 1 may be implemented by dedicated hardware, and a part thereof may be implemented by software or firmware. For example, the function of the acquisition unit 11 may be implemented by the processing circuit 102 which is dedicated hardware, and the function of the processing unit 12 may be implemented by the processor 103 reading and executing a program stored in the memory 104. As described above, the processing circuit can implement the above-described functions by hardware, software, firmware, or a combination thereof.

The program executed by the processor 103 may be received from a system (Comport) such as the World Wide Web (WWW) that connects a plurality of pieces of hardware via one or both of wired and wireless connections.

In addition, when the information processing device 1 trains a graph neural network to be described later, the information processing device 1 may transmit and receive parameters obtained by the training, particularly a weight matrix in the neural network, in the system.

The information processing device 1 may function as a training device that performs machine learning.

Note that the training device may be a device having general-purpose hardware that excels in parallel computation, such as a graphics processing unit (GPU), in addition to the CPU. Furthermore, the information processing device 1 may include a plurality of computers connected via a communication port.

In the following description, the information processing device 1 performs both training and inference, but training and inference may be performed by separate devices that operate independently of each other. In this case, one of these devices may be the information processing device 1, or both may be the information processing device 1.

Furthermore, the information processing device 1 may be a device that provides a plurality of virtual hardware environments in one piece of hardware and virtually handles individual pieces of virtual hardware as individual pieces of hardware.

Next, an operation of the information processing device 1 according to the first embodiment will be described.

FIG. 5 is a flowchart illustrating the information processing method according to the first embodiment, and illustrates a series of operations by the information processing device 1.

First, the acquisition unit 11 acquires a netlist (step ST1). For example, the acquisition unit 11 reads a circuit diagram model from the memory 104 illustrated in FIG. 4B, and converts a circuit diagram indicated by the circuit diagram model into a netlist. As a notation form of the netlist, there is one in which a wiring name is described after a component name is described. For example, there are formats such as Telesis, PADS, Allegro, Express PCB, Intergraph, and Scicards.

In addition, as the notation form of the netlist, there is a form in which the component name is described after the wiring name is described. For example, Calay, Mentor, or Vectron.

Furthermore, the notation form of the netlist also includes a form in which a component name and a wiring name are simultaneously described. For example, there are ComputerVision, Algorex, Multiwire, and the like.

In any notation method, the ground, the input, and the output are defined as wiring. The following netlist expresses a netlist related to an electric circuit for operating a switching power supply in the format of Telesis.
$PACKAGES
lt3489! LT3489;U1
ind! 2.2u;L1
schottky! 1N5818;D1
cap! 20u;C1
res! 28.7K;R1
res! 5.23K;R2
cap! 0.001u;C2
$NETS
N002; U1.1 U1.7
N003; U1.2 R1.2 R2.1
IN; U1.3 U1.6 L1.1
0; U1.4 C1.2 R2.2 C2.2
N001; U1.5 L1.2 D1.1
N004; U1.8 C2.1
OUT; D1.2 C1.1 R1.1
$END

The processing unit 12 extracts a component name list from the netlist (step ST2-1), and extracts a wiring name list from the netlist (step ST2-2). For example, the processing unit 12 stores all the component names included in the netlist in the component name list, and stores all the wiring names included in the netlist in the wiring name list.

Note that either the processing of step ST2-1 or the processing of step ST2-2 may be executed first, or may be executed simultaneously.

The component name list stores components having structural features such as semiconductors or capacitors, and does not include a ground terminal, an input terminal, and an output terminal. On the other hand, the wiring name list includes a ground wiring, an input wiring, and an output wiring that are a part of the wiring.

The processing unit 12 adds the ground wiring, the input wiring, and the output wiring included in the netlist to the component name list as a ground terminal, an input terminal, and an output terminal (step ST3-1). The processing unit 12 removes the ground wiring, the input wiring, and the output wiring from the wiring name list (step ST3-2). Thus, information indicating the ground terminal, the input terminal, and the output terminal remains in the component name list as component information, so that it is possible to suppress information deterioration when the electric circuit is converted into the graph network using the list information including the component name list.

Note that either the processing of step ST3-1 or the processing of step ST3-2 may be executed first, or may be executed simultaneously.

The row following “$PACKAGES” in the above netlist represents a component name, and the row following “$NETS” represents a wiring name. The component name “U1, L1, D1, C1, R1, R2, C2” extracted from the netlist is the component name list.

The wiring name “N002, N003, IN, 0, N001, N004, OUT” extracted from the netlist is the wiring name list. The input wiring is defined as “IN” and the output wiring is defined as “OUT”. Some netlists may not have names defined for input and output, but all netlists include respective wirings that correspond to an input and an output of an electric circuit. “0” is a wiring name indicating a ground wiring, and is always present on, for example, a substrate on which a semiconductor is mounted.

Note that, in this case, N001, N002, N003, and N004 are wiring names mechanically given by CAD to wirings to which the designer did not intentionally give wiring names.

The processing unit 12 adds a ground (GND), an input (IN), and an output (OUT) to the component name list. For example, the component name list to which the ground (GND), the input (IN), and the output (OUT) are added is “U1, L1, D1, C1, R1, R2, C2, GND, IN, OUT”. The ground (GND), the input (IN), and the output (OUT) do not have structural features unlike the circuit components and thus are not set in the component name list, but the processing unit 12 processes the ground (GND), the input (IN), and the output (OUT) as circuit components.

In the netlist, the number of the ground (GND), the input (IN), or the output (OUT) does not need to be one, and may be plural. For example, the ground may be divided into a system ground and a frame ground, and depending on an electric circuit, both may be connected by a capacitor, a resistor, an inductor, or the like. These grounds may be defined as different grounds.

The electric circuit includes not only a power supply terminal connected to a commercial power supply or a battery but also a plurality of types of input terminals such as an input terminal of an external signal.

Further, the electric circuit includes, for example, a plurality of output terminals such as an output terminal for outputting a signal indicating a rotation speed of a rotary machine in addition to an output terminal for outputting a signal connected to the rotary machine such as a motor.

The processing unit 12 removes the ground wiring (0), the input wiring (IN), and the output wiring (OUT) from the wiring name list. The wiring name list is “N002, N003, N001, N004”. This allows ground, inputs and outputs to be defined as components, rather than wirings, which can reduce information deterioration when converting from an electric circuit to a graph network.

For example, when the same electric circuit is represented using “PADS” which is another notation form of the netlist, the following is obtained, and in this case, the component name list and the wiring name list can be similarly created.

Note that, in any notation form of the netlist, the electric circuit is not established without a component and a wiring, so that the component name list and the wiring name list can always be created.
*PART*
U1 LT3489
L1 2.2u
D1 1N5818
C1 20u
R1 28.7K
R2 5.23K
C2 0.001u
*NET*
*SIGNAL*N002
U1.1 U1.7
*SIGNAL*N003
U1.2 R1.2 R2.1
*SIGNAL*IN
U1.3 U1.6 L1.1
*SIGNAL*0
U1.4 C1.2 R2.2 C2.2
*SIGNAL*N001
U1.5 L1.2 D1.1
*SIGNAL*N004
U1.8 C2.1
*SIGNAL*OUT
D1.2 C1.1 R1.1
*END*

Next, the processing unit 12 extracts a component name corresponding to a wiring name in the wiring name list from the component names in the component name list, and creates a combination list including the extracted component name (step ST4). For example, the processing unit 12 extracts, from the netlist, component names in the component name list corresponding to the wiring names in the wiring name list in the order of the list, and creates a combination list including the extracted component names. Here, the processing unit 12 includes the ground terminal, the input terminal, and the output terminal added to the component name list in the combination list.

Note that the “component name corresponding to the wiring name” is a component name indicating a component to which the wiring indicated by the wiring name is connected.

By including the ground terminal in the combination list, the information amount of the combination list can be reduced. In general, many components in an electric circuit are connected to ground GND. For example, in a case where N components are connected to the ground GND, the combination list includes N combinations of the ground GND and the components.

Note that, when the ground GND is not defined, it is necessary to create the number of combinations of the ground GND and the components proportional to the square of N.

Since the electric circuit is not established unless components are connected by wiring, it is possible to always create the combination list as long as the electric circuit functions normally.

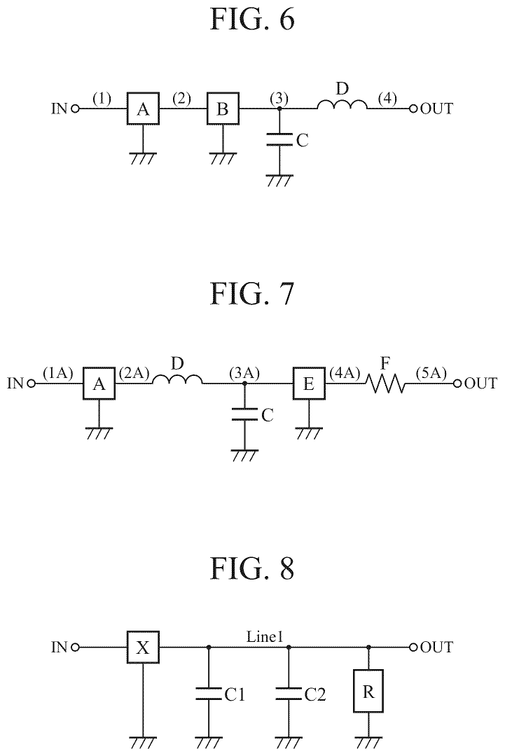

FIG. 6 is a circuit diagram illustrating an example (1) of the electric circuit. A netlist of the electric circuit illustrated in FIG. 6 is as follows.
#component
A
B
C
D
#wiring
(1); IN,A
(2); A,B
(3); B,C,D
(4); D,OUT
GND; A,B,C

The component name list extracted from the netlist becomes “A, B, C, D, IN, OUT, GND” by adding “IN”, “OUT”, and “GND”.

The wiring name list becomes “(1), (2), (3), (4)” by removing “IN”, “OUT”, and “GND”.

In a netlist in which a wiring connected to a ground terminal is not defined, a wiring is provided between the ground and a component, and a name is given to the wiring.

That is, from the “GND;A,B,C” in the netlist of the electric circuit illustrated in FIG. 6, for example, the ground is represented by “G”, and component names are connected to give wiring names of “G-A”, “G-B”, and “G-C”. As a result, the wiring name list is “(1), (2), (3), (4), G-A, G-B, G-C”.

In the component name list “A, B, C, D, IN, OUT, GND”, component names corresponding to wiring names in the wiring name list “(1), (2), (3), (4), G-A, G-B, G-C” are sequentially extracted from the netlist to obtain the following combination list.
(1); IN,A
(2); A,B
(3); B,C,D
(4); D,OUT
G-A; GND,A
G-B; GND,B
G-C; GND,C

Subsequently, the processing unit 12 determines whether or not there are three or more component names corresponding to one wiring name among the component names in the combination list (step ST5). Here, when it is determined that there are less than three component names corresponding to one wiring name in the combination list (step ST5; NO), the processing unit 12 replaces the component name in the combination list with the identification number (step ST6).

On the other hand, when it is determined that there are three or more component names corresponding to one wiring name in the combination list (step ST5; YES), the processing unit 12 decomposes them into a combination of two component names (step ST7). For example, when a component name held by a certain wiring name, that is, a component name corresponding to one wiring name is [capacitor, coil, resistor], the processing unit 12 decomposes the component name into three combinations of [capacitor, coil], [coil, resistor], and [resistance, capacitor]. Similarly, in a case where the component name is [capacitor, coil, resistor, semiconductor], the processing unit 12 decomposes the component name into six combinations of [capacitor, coil], [capacitor, resistor], [capacitor, semiconductor], [coil, resistor], [coil, semiconductor], and [resistor, semiconductor].

The processing unit 12 adds combinations obtained by decomposition into combinations of two component names each to the list, and removes the combination having three or more component names before the decomposition from the combination list. However, this processing is processing for creating an adjacency matrix in the graph network, and may not be decomposed as long as the adjacency matrix can be directly created from the combination list.

For example, in the netlist, since (3);B,C,D corresponds to a combination of three or more component names, the processing unit 12 decomposes it into (B, C), (C, D), and (D, B). As a result, the following combination list is obtained for the circuit diagram illustrated in FIG. 6.
(1); (IN,A)
(2); (A,B)
(3); (B,C),(C,D),(D,B)
(4); (D,OUT)
G-A; (GND,A)
G-B; (GND,B)
G-C; (GND,C)

FIG. 7 is a circuit diagram illustrating an example (2) of the electric circuit. The circuit diagram illustrated in FIG. 7 is the following netlist.
#component
A
C
D
E
F
#wiring
′; IN,A
′; A,D
′; C,D,E
(4A); E,F
(5A); F,OUT
GND; A,C,E

The component name list included in the netlist is “A, C, D, E, F, GND, IN, OUT”, and the wiring name list is “(1A), (2A), (3A), (4A), (5A), G-A, G-C, G-E”. The processing unit 12 extracts the component name corresponding to each wiring name in the wiring name list from the netlist to create the following combination list.
(1A); IN,A
(2A); A,D
(3A); C,D,E
(4A); E,F
(5A); F,OUT
G-A; GND,A
G-C; GND,B
G-E; GND,E

Subsequently, in a case where each combination list has three or more component names, the processing unit 12 disassembles the component names. For example, the processing unit 12 creates the following combination list by decomposing the combination “(3A); C, D, E” into combinations of two component names each.
(1A); (IN,A)
(2A); (A,D)
(3A); (C,D),(D,E),(E,C)
(4A); (E,F)
(5A); (F,OUT)
G-A; (GND,A)
G-C; (GND,B)
G-E; (GND,E)

Hitherto, the description has been made on the assumption that component names other than the same component do not match, but in a case where the same component name is used for a circuit component having another function, the processing unit 12 changes the component name.

Conversely, when different component names are used for the same circuit component, the processing unit 12 changes the component name. When the number of component names is large and it is difficult to unify the component names, it is easy to unify the component names by using the model number of each component manufacturer.

The processing unit 12 defines a common unique identification number for each component type or component model number indicated by each component name in the component name list (step ST8), and replaces each component number in the component name list with an identification number (step ST9).

The processing unit 12 replaces each component name included in the component name list and the combination list with an identification number. The component name list and the combination list thus obtained are output as list information.

By using the list information including the component name list and the combination list in which the component name is replaced with the identification number, circuit information can be expressed by numerical values, and information deterioration of the graph network is reduced as described above, so that the original electric circuit can be created by using the graph network.

In addition, the identification number may be defined for each type of component that is a feature of the component.

The type of the component can be expressed by information such as a capacitor, a coil, a power supply IC, or a diode. The number of types of components is approximately 100 or less depending on the classification method. Thus, the number of types of components is relatively small. For example, the processing unit 12 replaces the component name by using the serial number set for each type of component as the identification number.

Furthermore, the identification number may be defined for each model number of the component.

In a case where the number of components used in the electric circuit is limited, the identification number for each model number of the component is relatively small. In this case, by using the identification number defined by the model number of the component, it is possible to prevent information deterioration when the list information is converted into the graph network.

In step ST8, the processing unit 12 defines an identification number by the following method and assigns the defined identification number to a component name.

The component name list related to the electric circuit illustrated in FIG. 6 is “A, B, C, D, IN, OUT, GND” as described above, and the component name list related to the electric circuit illustrated in FIG. 7 is “A, C, D, E, F, GND, IN, OUT” as described above.

The processing unit 12 combines these component name lists to create a component name list of “A, A, B, C, C, D, D, E, F, GND, GND, IN, IN, OUT, OUT”. The component name list includes a plurality of the same component names.

The processing unit 12 removes duplication of component names to create a component name list “A, B, C, D, E, F, GND, IN, OUT”.

Subsequently, the processing unit 12 assigns identification numbers in such a manner that each component in the component name list has different identification numbers. When a natural number is used as the identification number, the component name list in which the component name is replaced with the identification number is as follows. Note that the identification number is not necessarily a continuous number, and may be a letter or a symbol.
A→1
B→2
C→3
D→4
E→5
F→6
GND→7
IN→8
OUT→9

The order may be arbitrarily changed, where the identification number of the component name “GND” is “0”, the identification number of the component name “IN” is “1”, and the identification number of the component name “OUT” is “2”.

In addition, the identification number may be a number corresponding to a circuit constant of the component, a model number of the component, a manufacturer of the component, or a withstand voltage of the component. For example, the same identification number is assigned to components having the same function such as a power supply, a memory, and a CPU.

For example, when an isolated power supply and a non-isolated power supply are separated in the switching power supply, the same identification number is assigned to the isolated power supply, and the same identification number is assigned to the non-isolated power supply.

In addition, the same identification number may be assigned to operations such as boosting, stepping down, or lifting and lowering.

Further, an identification number may be assigned depending on a circuit constant of a passive element.

For example, the same identification number may be assigned to a capacitor having a capacitance of 1.0 μF, and the same identification number may be assigned to a capacitor having a capacitance in a range of 1.0 μF to 3.3 μF.

Further, the definition of the identification number may be changed in accordance with the request of the user.

Furthermore, an identification number may be assigned to each model number set for a component by a component manufacturer.

The method of defining the identification number may be changed depending on the electric circuit to be handled.

For example, when the component name is replaced with the identification number for each component type (capacitor, coil, resistor, semiconductor, and the like), the component name list related to the electric circuit illustrated in FIG. 6 becomes “1, 2, 3, 4, 7, 8, 9”, and the combination list becomes “(8,1), (1,2), (2,3), (3,4), (4,2), (4,9), (7,1), (7,2), (7,3)”.

In addition, the component name list related to the electric circuit illustrated in FIG. 7 is “1, 3, 4, 5, 6, 7, 8, 9”, and the combination list is “(8,1), (1,4), (3,4), (4,5), (5,3), (5,6), (6,9), (7,1), (7,2), (7,5)”.

The processing unit 12 repeats the series of processes described above, thereby creating a component name list and a combination list relating to all the circuit diagrams. Since the definition of the identification number is arbitrary, the use of the circuit can be changed according to the purpose of use of the circuit by determining the identification number according to the feature of the component of interest. For example, in the problem of predicting the type of the component, while the model number is redundant information to be used as the identification number, if the manufacturer of the component is used as the identification number, there is a possibility that the information is insufficient and correct prediction cannot be performed. Thus, it is necessary to select the identification number depending on the purpose of use, and when the identification number is correctly selected, the amount of calculation when predicting the type of the component is small, and the prediction accuracy can be improved.

Further, a plurality of identification numbers may be assigned to one component name.

For example, identification numbers corresponding to the model number of the component, the type of the component, and the circuit constant of the component may be assigned. In this case, for example, the component name list of the electric circuit illustrated in FIG. 7 is “(1,3,0), (3,3,7), (4,5,3), (5,2,0), (6,8,1), (7,1,0), (8,1,0), (9,1,0)”.

Since the types of components of “IN”, “OUT”, and “GND” as component names are all wirings, the identification number is defined as “1”, and components represented by the identification number “1” assigned to a semiconductor, the identification number “5” assigned to another semiconductor, and the component names “IN”, “OUT”, and “GND” are input terminals, output terminals, and ground, and have no circuit constant. In this case, for example, the identification number is defined as “0”.

For example, a circuit constant may also be provided in the semiconductor in consideration of characteristics inside the semiconductor, or different identification numbers may be assigned to types of components indicated by “IN”, “OUT”, and “GND”.

The method of assigning the identification number may be any method as long as the method is based on a rule common among the circuits.

The identification number only needs to be a real number and is not necessarily a natural number.

The circuit constant of the component may be directly input as the identification number.

For example, the circuit constant used in a general circuit ranges from a maximum number f (femto) to several 100 G (giga) and about 10 raised to the power of 20. Thus, if the circuit constant is used as it is as the identification number, a large number becomes dominant.

In addition, a small value may be rounded or changed to a different value due to a calculation error. In order to avoid them, a function including a logarithm may be used as the circuit constant. For example, the function is f(x)=log 10(x)+15. Here, +15 is −log 10 (f=1 femto). In this manner, f(x) can be converted as a real number equal to or greater than 0. In addition, in order to avoid that it becomes 0 when if is included and it is not possible to determine which component is included, log 10(x)+16 or log 10(x)+15+(minute amount of more than 0 and less than 1) may be used. Further, for the sake of simplicity, the case where the base of the logarithm is 10 has been described, but the base need not be 10.

Since there are many cases where the component constant is sufficient with an accuracy of one digit or less, in that case, the identification number may be defined by order by rounding the value as follows.

1f→1,10f→2,100f→3,1n→4,10n→5,100n→6,1u→7,10u→8,100u→9,1m→10,10m→11,100m→12,1→13,10→14,100→15,1k→16,10k→17,100k→18,1M→19,10M→20,100M→21,1G→22,10G→23,100G→24.

Through the series of processes described above, the circuit diagram can be converted into a netlist, and the netlist can be converted into a component name list and a combination list. Using the component name list and the combination list, a graph network in graph theory can be created.

The graph network can be used to search for similar circuits, which is difficult with a netlist.

For example, the processing unit 12 can search for a semiconductor, a capacitor, a coil, ground, and a semiconductor loop path by sequentially searching for adjacent matrices created using the combination list. In particular, in an electric circuit using a specific circuit component, identification numbers of components constituting the circuit are sequentially searched for.

For example, the processing unit 12 refers to a database including a semiconductor as a noise source and a terminal number of the semiconductor, performs a search process of continuously searching for adjacent components from the electric circuit under a condition that the same component is not passed twice or more with a terminal corresponding to the terminal number as a starting point, extracts a current loop representing the semiconductor, and terminates the search process.

Specifically, with the terminal of the semiconductor to be searched for as a search start point, processing of searching for one or more adjacent components from the start point and searching for one or more circuit components adjacent to the components is continuously performed. However, the search is performed under a condition that a component other than the semiconductor, which is the start point of the search, does not pass twice or more. This makes it possible to avoid a search against a physical phenomenon in which the current returns to the original state or the current stops halfway.

The processing unit 12 ends the search process when terminating at any terminal other than the terminal serving as the start point of the search among semiconductors serving as search start points.

The path created by this search process is referred to as the “current loop” above. That is, the above processing is equivalent to the processing of extracting a current loop path in the current law that is Kirchhoff's law (Kirchhoff's first law).

The terminal may be any terminal. For example, although the number of ground terminals is the largest, in the case of a differential line, any terminal of the differential signal is a start point, and the opposite terminal is an end point.

Thus, for example, it is possible to detect extraction of a noise filter or the like on the basis of an algorithm, or it is possible to estimate impedance of a propagation path through which the current can flow and predict which current loop the current most easily flows from the circuit.

In this manner, the processing unit 12 can extract features of the semiconductor to be searched for and features of the current loop indicating the semiconductor from one or a plurality of electric circuits including one or more semiconductors, and search for a semiconductor similar to the semiconductor to be searched using the extracted features of the semiconductor and the features of the current loop.

Furthermore, the processing unit 12 may determine whether or not there is a component indicating a noise filter in the current loop. As an example, a case will be described in which a path returning from a power input terminal of a semiconductor to a ground terminal of the semiconductor via a ground capacitor (Y capacitor) and the ground is detected. In the present embodiment, the ground capacitor and the ground are defined as nodes of the graph network. Thus, the path can be detected by determining the presence or absence of a path from the node (semiconductor) to be the start to the same node as the start via two nodes. For this detection, if all the current loops passing through the two nodes are extracted, and one node of the extracted current loops is a capacitor and the other node is ground, a current loop having a noise filter can be extracted.

Furthermore, a database having a model number serving as a noise countermeasure component is created in advance in the information processing device 1. By confirming whether or not the extracted capacitor is included in the database, the processing unit 12 can determine that there is a noise filter in the current loop when the extracted capacitor is included.

Furthermore, in order to limit nodes that can be noise sources and reduce the amount of calculation, a database having model numbers of circuit components that can be noise sources is created in advance in the information processing device 1. The search targets can be reduced by the processing unit 12 setting only an applicable node as the start point of the search.

Although the example of the ground capacitor has been described in the above description, a T-type filter, a π-type filter, or the like can be similarly extracted.

In addition, it is possible to confirm the presence or absence of connection between any components in a similar manner.

Furthermore, by using attribute information held by each node, it is possible to predict a frequency characteristic such as an impedance, a current amount, or a voltage drop between components or a time waveform.

The processing unit 12 can extract a similar circuit by creating a current loop for each terminal of the semiconductor and analyzing circuit components through which the current loop passes.

Through the above search processing, the processing unit 12 can search for a noise filter circuit or a similar circuit without depending on the number of components or the number of wirings in the electric circuit, the number of ground or input/output ports, or the like. Thus, a search error can be reduced by searching for a path adjacent to the semiconductor, an input connector, or an output connector serving as a noise source provided with the noise filter.

Note that, as the semiconductor serving as a noise source, a model number of a component can be extracted as text data from the netlist. In addition, in the circuit diagram, inputs and outputs are often described as input symbols and output symbols, but may also be described as input connectors and output connectors to which the model numbers of the connectors are assigned. Thus, the above-described database in which a semiconductor, a noise countermeasure component, an input connector, or an output connector serving as a noise source is registered is prepared, and only text data is extracted by referring to the database, whereby omission of the search can be suppressed.

In addition to the search for the noise source or the noise filter, a node and an edge are provided with a resistance component or a delay component, so that the processing unit 12 can calculate impedance between two components and estimate a path through which the current flows most or a path through which the pulse signal arrives earliest.

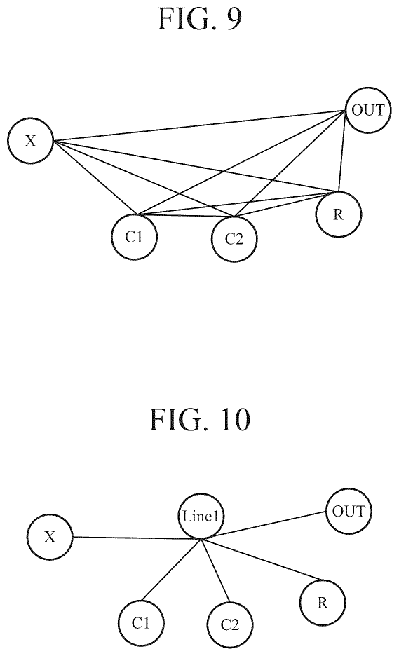

In a case where the electric circuit has a plurality of components connected in parallel to one wiring, the number of combinations of components in the combination list increases in the processing so far. FIG. 8 is a circuit diagram illustrating an example (3) of the electric circuit. The electric circuit illustrated in FIG. 8 is a circuit in which one wiring Line1 is connected between an input terminal IN and an output terminal OUT, and a capacitor C1, a capacitor C2, and a resistor R are connected in parallel to the wiring Line1. The information processing device 1 that handles ground, input, and output as components creates list information in which the electric circuit is converted into the graph network illustrated in FIG. 9 below.

FIG. 9 is a schematic diagram illustrating a graph network in which nodes are connected by edges. In the graph network illustrated in FIG. 9, components in the electric circuit illustrated in FIG. 8 are represented by nodes, and these components are connected by edges. The information processing device 1 creates list information that handles ground, input, and output as components. Thus, the list information created by the information processing device 1 is converted into a graph network in which, for example, a semiconductor X, a capacitor C1, a capacitor C2, a resistor R, and an output terminal OUT are represented as nodes, and all the nodes are connected by edges. In FIG. 9, description of a node indicating the input terminal IN and a node indicating the ground is omitted for simplicity of description.

Note that the graph network has a feature that a component name is a node, and a node adjacent to any node is a node having a component name.

When the electric circuit has a plurality of components connected in parallel to one wiring, the combination of the components corresponding to each other in the combination list increases in proportion to about the square of the number of components connected in parallel to the wiring. In FIG. 9, since three components (capacitor C1, capacitor C2, and resistor R) are connected in parallel to one wiring Line1, nine combinations, which is the square of 3, are generated. For example, there is a large-scale circuit in which 10 or more bypass capacitors are connected in parallel to one wiring. Such a circuit greatly increases the number of combinations. For this reason, the calculation amount required for searching the current loop exponentially increases, and the search time also increases.

Note that, also in the graph network illustrated in FIG. 9, when searching for all current loops starting from a specific component name node, it is possible to exhaustively search for nodes so as to satisfy a condition that a node that has been passed once is not passed twice. However, in a case where the component name nodes are adjacent to each other, as described above, it is necessary to include a number of components proportional to about the square of the number of components connected in parallel to one wiring line. For example, as illustrated in FIG. 9, when the number of components connected in parallel is three, it is difficult to calculate a path returning to a node having the same component name as the start point via a node corresponding to each component name of the three components.

Accordingly, the information processing device 1 may create a combination list including wiring names and component names so as to suppress an increase in the number of combinations of component names for a large-scale circuit in which a plurality of components is connected in parallel to one wiring as described above. For example, the processing unit 12 extracts a component name list and a wiring name list from the netlist of the electric circuit, and creates a component name list that is updated by adding component names indicating a ground terminal, an input terminal, and an output terminal, a wiring name list that is updated by removing wiring names indicating a ground wiring, an input wiring, and an output wiring, and a combination list including an extracted component name obtained by extracting a component name corresponding to a wiring name in the updated wiring name list from the component names in the updated component name list and a wiring name corresponding to the extracted component name, and outputs the updated component name list and combination list.

FIG. 10 is a schematic diagram illustrating a graph network in which nodes are connected via wiring nodes. As illustrated in FIG. 10, the processing unit 12 extracts a combination of a component name corresponding to a component connected by a wiring indicated by each wiring name in the wiring name list and the each wiring name as a combination list. The graph network converted from the list information has characteristics that a component name and a wiring name are represented by nodes, and a node adjacent to a node having any component name is a node of a wiring name. Thus, the number of combinations can be set to a number proportional to the first power of the number of components.

Also in the graph network illustrated in FIG. 10, when searching for all current loops starting from a specific component name node, it is possible to exhaustively search for nodes so as to satisfy a condition that a node that has been passed once is not passed twice.

On the other hand, in the graph network, the component name node and the wiring name node are adjacent to each other, and a route returning to the start point via four wiring name nodes and three component name nodes instead of nodes that are three circuit components (capacitor C1, capacitor C2, and resistor R) is searched for. However, since the wiring connected to each node is linearly proportional, the calculation amount required for the search does not become exponentially large.

As an example of the experiment, when a current loop of a large-scale circuit having 1,000 or more components was searched in the same computer environment, it took 10 minutes when component name nodes were adjacent in the graph network, whereas the search was completed within 1 second when the component name node and the wiring name node were adjacent to each other. Even in this example, a particularly large effect can be obtained in the current loop search.

However, in a case where the component name node and the wiring name node are adjacent to each other as compared with a case where the component name nodes are adjacent to each other, it is advantageous in a case where the number of components connected in parallel to one wiring is large, but it is disadvantageous in a case where the number of components connected in parallel is small because the number of wiring name nodes increases.

Thus, it is desirable to selectively use the two methods corresponding to the scale of the circuit or the number of components connected in parallel to one wiring. For example, if a current loop of a circuit having about 100 components is searched, it is often better to use a graph network having adjacent component name nodes.

Note that regardless of whether the wiring name node is included or not, in both the methods described above, paths having the same looped path and opposite directions can be obtained. Thus, only one path may be left and the other path may be removed in the post-processing. However, in a case where the direction of the current is known and the graph is a directed graph, only one path is extracted, and thus the post-processing may not be performed.

The processing unit 12 may replace an element corresponding to a passive circuit in the feature amount matrix with a function value calculated by substituting a circuit constant of a component into a function including a logarithm.

In a component having a circuit constant, by changing an element corresponding to a passive circuit in a feature amount matrix with a function value obtained by applying a function including a logarithm to the circuit constant, conversion to a graph network including the circuit constant can be performed.

The component having a circuit constant is a resistor, a capacitor, or a coil, but may be a small signal circuit such as an operational amplifier. Components other than resistors, capacitors, and coils may also be circuit components with circuit constants, as long as they can be converted under certain conditions into components composed of resistors, capacitors, and coils.

Components with physical dimensions also have parasitic components such as stray capacitance, residual inductance or residual resistance. Thus, the processing unit 12 disassembles one component having a parasitic component into components having only two or more resistors, capacitors, or coils. The decomposition can be implemented by predicting an equivalent circuit from impedance measurement and determining a circuit constant of the equivalent circuit. Thus, even a circuit having complicated component characteristics can be expressed by a graph network.

A circuit constant of a component having only one characteristic is assigned to a component name in the component name list. Since circuit constants often have a width of 20 or more digits from 1p to 1G, except for special examples, the circuit constants may be logarithmically multiplied. By applying logarithm to the circuit constant, it is possible to prevent a capacitor of 1 pF, for example, from being buried due to a calculation error.

The processing unit 12 may perform both or one of normalization and standardization on the function value.

For example, normalization is performed on a result obtained by performing logarithm on a circuit constant.

When inputting a graph network into a graph neural network, an activation function in the graph neural network reacts to a real number from 0 to 1.

Normalization is performed on the result of performing logarithm on the circuit constant, and bijection is performed to a real number equal to or more than 0 and equal to or less than 1, or more than 0 and equal to or less than 1, whereby the result of performing logarithm on the circuit constant can be associated with an activation function of the real number.

Standardization may be performed on a result of performing logarithm on the circuit constant.

For example, in a distribution of the result of performing logarithm on the circuit constant of the capacitor used for the electric circuit, when there are many capacitors of 100 μF or less and there is even one capacitor such as 100 F, the distribution of the result of performing the logarithm on the circuit constant varies, and the difference in the result of performing the logarithm on the circuit constant for each capacitor is estimated to be small.

Thus, by standardizing the result of logarithm of the circuit constant, it is possible to reduce the variation in distribution.

In addition, since the range of the circuit constant is different for each type of circuit component, different normalization or standardization may be performed for each type of circuit component. For example, while a capacitor of 100 F is included in a large category of the capacitor, a resistor of 100Ω is included in a small category of the resistor, and thus the range becomes large. Thus, for example, in the case of a capacitor, the distribution is adjusted in such a manner that 1 μF is at the center, and in the case of a resistor, the distribution is adjusted in such a manner that 100Ω is at the center, whereby the rounding error is reduced, and the accuracy of estimation of the result of performing logarithm on the circuit constant is improved.

In addition, the processing unit 12 may perform standardization after normalization on the result of performing logarithm on the circuit constant, or may perform normalization after standardization. By combining normalization and standardization in this way, both effects are obtained.

A circuit component having no circuit constant does not become information by assigning the same numerical value such as “0” or “1” as an identification number. Thus, a feature amount list created by additional information can be expressed by a matrix.

For example, in the case of a capacitor or a coil, the capacitor or the coil can be classified by a circuit constant and has two terminals, and thus information deterioration does not occur when the graph network is converted into an electric circuit.

On the other hand, in a case where two or more semiconductors are included in one electric circuit and two or more semiconductors of the same model number are included, information deterioration occurs when conversion from a graph network to an electric circuit is performed. Thus, additional information indicating that the components are different may be added to the component name list for the semiconductor.

For example, a real number larger than 0 and equal to or smaller than 1 is divided by the number of semiconductors, and different real numbers are assigned to the respective semiconductors as additional information.

When there are two semiconductors having the same model number in one electric circuit, different real numbers are assigned such as assigning 0.3 to one semiconductor and assigning 0.6 to the other semiconductor.

In addition, if it is only known that a component in an electric circuit is a semiconductor, and the electric circuit is a circuit including 10 semiconductors, 0.1 to 1.0 may be assigned in increments of 0.1 as the additional information.

Note that the additional information only needs to have different numerical values, and real numbers may be assigned in any order.

Note that, when the identification number is not used, the processing unit 12 may directly output the component name list and the combination list as the list information without replacing the component name with the identification number.

### Modification 1

In the information processing device 1 according to Modification 1, the processing unit 12 uses the graph network to train a graph neural network by using the component name list as a node in the graph network, the wiring name list as an edge in the graph network, and the combination list as an adjacency matrix in the graph network.

The training of the graph neural network is unsupervised learning when a dataset of training data includes only nodes and edges.

On the other hand, in a case where correct answer data can be obtained by circuit simulation or experiment, the processing unit 12 trains the graph neural network using nodes, edges, and the correct answer data as a dataset of training data.

Further, the processing unit 12 trains the graph neural network by including attribute information of an edge (edge attribute) such as frequency characteristics of an edge.

Furthermore, the processing unit 12 trains the graph neural network by using characteristics of a component for each circuit constant or for each semiconductor as attribute information of a node (node attribute).

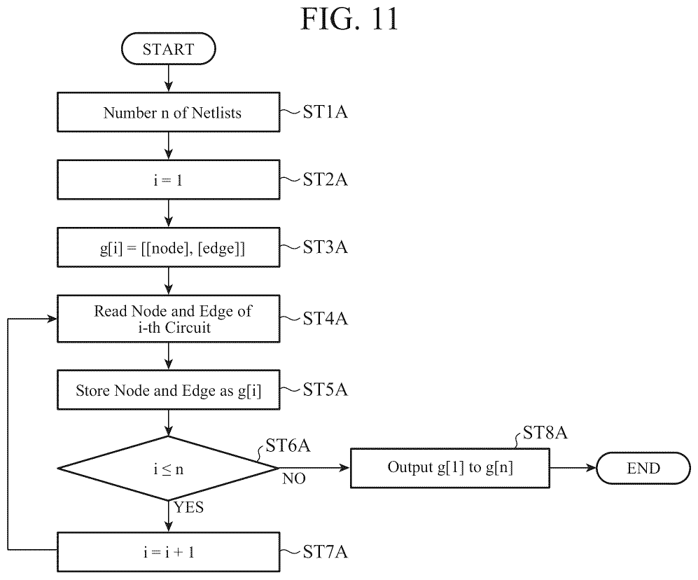

FIG. 11 is a flowchart illustrating a data input processing example (1) to the graph network in the first embodiment. Assuming that the number of electric circuits is n, n netlists equal to the number of electric circuits can be generated, and thus the processing unit 12 sets the n netlists as processing targets (step ST1A). The processing unit 12 sets “1” as the parameter i (step ST2A).

The processing unit 12 sets the value of the parameter i to the function g[i]=[[node], [edge]](step ST3A). The processing unit 12 extracts the component name list and the wiring name list from the i-th netlist acquired by the acquisition unit 11.

The processing unit 12 reads the component name list extracted from the i-th netlist as a node of the graph network, and reads the wiring name list as an edge of the graph network (step ST4A). The processing unit 12 sets a node and an edge related to the i-th netlist as one dataset, and stores the dataset in a storage area such as the memory 104 in association with the function g[i](step ST5A).

The processing unit 12 determines whether or not the parameter i is equal to or less than n (step ST6A). If the parameter i is equal to or less than n (step ST6A; YES), the processing unit 12 adds “1” to the parameter i (step ST7A), and returns to the processing of step ST4A.

On the other hand, when it is determined that the parameter i is larger than n (step ST6A; NO), the processing unit 12 outputs datasets respectively associated with g[1] to g[n](step ST8A).

The nodes are a matrix of (the number of components of each circuit+ground terminal+input terminal+output terminal)×(the number of feature amounts of nodes). For example, in the electric circuit illustrated in FIG. 6, the nodes are a matrix of 7×1. Note that, although the input terminal and the output terminal have been described as one electric circuit, it is sufficient that the input terminal and the output terminal have one or more terminals, and in this case, the column of the matrix becomes large.

Furthermore, the number of feature amounts of the nodes may be input as one hot, and in this case, when the number of feature amounts of the nodes is M (for example, as in the electric circuit illustrated in FIG. 6, M=4 when a capacitor, a coil, a first semiconductor, and a second semiconductor are included as types of components), the nodes have a matrix of 7×M. The edges are a matrix of 2×(the number of edges). Here, “2” multiplied by (the number of edges) means any two components in the component name list, and the edge is a matrix indicating that these two components are connected by the number of edges.

Note that, in a case where the direction of the current is known, a directed graph may be used. In the directed graph, when the order in which the current of the components in the combination list flows is expressed as, for example, (1,2), it means directions from 1 to 2 or directions from 2 to 1 by definition. There may be an edge that is bidirectional like an undirected graph, and in that case, (2,1) only needs to be further added to (1,2). When bidirectional edges are considered, in a case where the undirected graph is a matrix of 2×(the number of edges), the matrix is a matrix of 4×(the number of edges) at the maximum in the directed graph.

In the case of the electric circuit illustrated in FIG. 6, since the number of combinations in the combination list is nine (8,1), (1,2), (2,3), (3,4), (4,2), (4,9), (7,1), (7,2), and (7,3), the number of nodes is a 2×9 matrix. An element of this matrix is an identification number included in the component name list as a node. This means that a component included in a certain circuit does not form an edge with a component included in another circuit.

In the graph neural network, individual circuits can be processed in order, but can be parallelized by using dedicated hardware such as a GPU.

In particular, when the number of circuits increases to several 1,000 or more, it is desirable from the viewpoint of calculation speed or calculation efficiency to process the circuits together rather than to calculate the individual circuits in order. Thus, combinations of nodes and edges that can be stored in the memory in whole or at a time are collectively input.

In this example, since there is no correct answer data, unsupervised learning is performed.

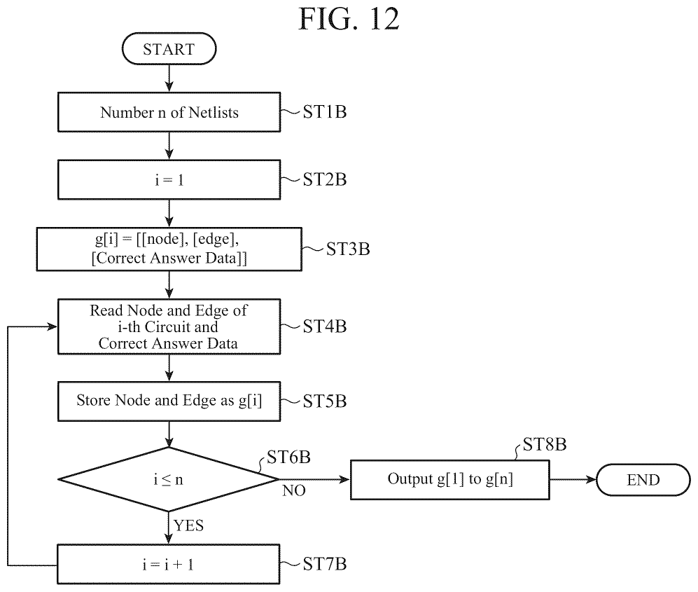

FIG. 12 is a flowchart illustrating a data input processing example (2) to the graph network in the first embodiment. Assuming that the number of electric circuits is n, n netlists equal to the number of electric circuits can be generated, and thus the processing unit 12 sets the n netlists as processing targets (step ST1B). The processing unit 12 sets “1” as the parameter i (step ST2B).

The processing unit 12 sets the value of the parameter i to the function g[i]=[[node], [edge], [correct answer data]] (step ST3B). The processing unit 12 extracts the component name list and the wiring name list from the i-th netlist acquired by the acquisition unit 11, and acquires correct answer data obtained in advance.

The processing unit 12 reads the component name list extracted from the i-th netlist as a node of the graph network, reads the wiring name list as an edge of the graph network, and further reads correct answer data (step ST4B). The processing unit 12 sets the node, the edge, and the correct answer data related to the i-th netlist as one dataset, and stores the data in a storage area such as the memory 104 in association with the function g[i] (step ST5B).

The processing unit 12 determines whether or not the parameter i is equal to or less than n (step ST6B). If the parameter i is equal to or less than n (step ST6B; YES), the processing unit 12 adds “1” to the parameter i (step ST7B), and returns to the processing of step ST4B.

On the other hand, when it is determined that the parameter i is larger than n (step ST6B; NO), the processing unit 12 outputs data sets respectively associated with g[1] to g[n] (step ST8B).

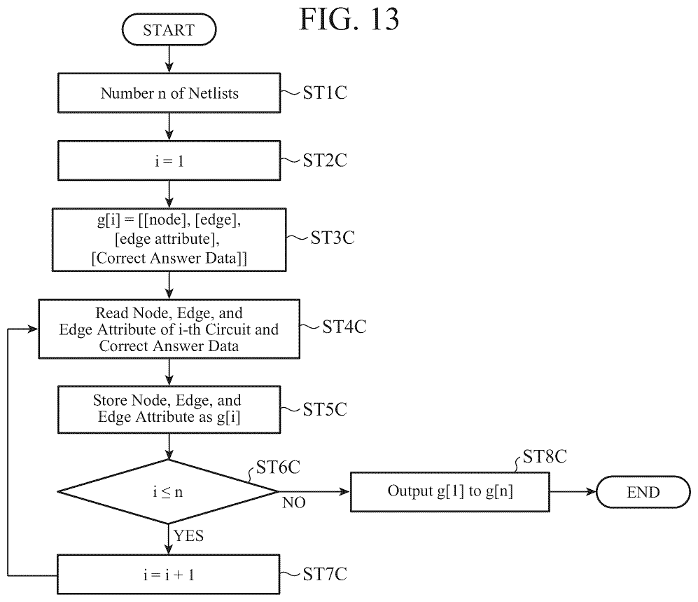

FIG. 13 is a flowchart illustrating a data input processing example (3) to the graph network in the first embodiment. Assuming that the number of electric circuits is n, n netlists equal to the number of electric circuits can be generated, and thus the processing unit 12 sets the n netlists as processing targets (step ST1C). The processing unit 12 sets “1” as the parameter i (step ST2C).

The processing unit 12 sets the value of the parameter i to the function g[i]=[[node], [edge], [edge attribute], [correct answer data]] (step ST3C). The processing unit 12 extracts the component name list and the wiring name list from the i-th netlist acquired by the acquisition unit 11, and acquires the attribute of the edge and the correct answer data obtained in advance.

The processing unit 12 reads the component name list extracted from the i-th netlist as a node of the graph network, reads the wiring name list as an edge of the graph network, and further reads an attribute of the edge and correct answer data (step ST4C). The processing unit 12 sets the node, the edge, the edge attribute, and the correct answer data related to the i-th netlist as one dataset, and stores them in a storage area such as the memory 104 in association with the function g[i](step ST5C).

The processing unit 12 determines whether or not the parameter i is equal to or less than n (step ST6C). If the parameter i is equal to or less than n (step ST6C; YES), the processing unit 12 adds “1” to the parameter i (step ST7C), and returns to the processing of step ST4C.

On the other hand, when it is determined that the parameter i is larger than n (step ST6C; NO), the processing unit 12 outputs datasets respectively associated with g[1] to g[n] (step ST8C).

The dataset obtained as described above can be used for self-supervised learning which is one of clustering, autoencoder, and contrastive learning, for example. The clustering can be used for the classification of node types or the classification of edge types.

The autoencoder is training of a graph neural network aimed at obtaining the same output data as the input data after passing through the graph neural network. In the autoencoder, a plurality of circuits can be abstracted and held.

Furthermore, although self-supervised learning is similar to clustering, for example, each input data can be classified, and similar circuits can be classified into any number of sets.

These are examples, and it is also possible to predict the presence or absence of an edge between nodes or predict the presence or absence of a node by combining a plurality of technologies.

Note that, as a neural network that handles data of an electric circuit as a graph network, a graph convolutional neural network, a graph attention network, and the like are known in addition to a graph neural network.

For example, any one may be used depending on a characteristic of data or a characteristic of correct answer data, such as one suitable for a large-scale model and one excelling in an adjacency matrix created using an edge and sparse.

The processing unit 12 trains the graph neural network by using the type of the circuit diagram as correct answer data and using this as teacher data and using, for example, 3,362 types of sample circuits handled by the circuit simulator as training data.

The sample circuit includes nine types of circuits for operating a semiconductor, namely, Switch circuits (89), Reference circuits (59), ADC circuits (27), DAC circuits (29), comparator circuits (40), filter circuits (25), power supply circuits (2272), and operational amplifier circuits (665).

The processing unit 12 trains a graph neural network for classifying electric circuits using a dataset obtained by combining a graph network and circuit classification data assigned to each of the plurality of electric circuits as training data, and inputs a graph network not used for the training to the graph neural network, thereby classifying the electric circuits.

For example, training a graph neural network that solves a classification problem of classifying electric circuits into the nine types is performed. Here, 2,300 pieces of randomly acquired data were set as training data, and the remaining 897 pieces of data were set as test data not used for training. The graph neural network of the training result was randomly classified, and the distribution of the classification problem between the training data and the test data was made similar. In addition, the same training data and test data were used in calculations of all graph neural networks described in the embodiments.

Note that, in the above conditions, the node of the component constant or the component model number is not used, and each node is only an identification number for each type of component such as a semiconductor, a capacitor, or a coil.

This is for preventing the classification of a circuit from the model number because, in the circuit classification problem, it is expected to perform prediction from connection information between circuit components, but if the model number of the component is included in the data, the classification from the model number is possible.

Furthermore, only information for connecting each identification number was input for the edge. At this time, since the undirected graph does not consider the direction of the current, the adjacency matrix becomes a symmetric matrix.

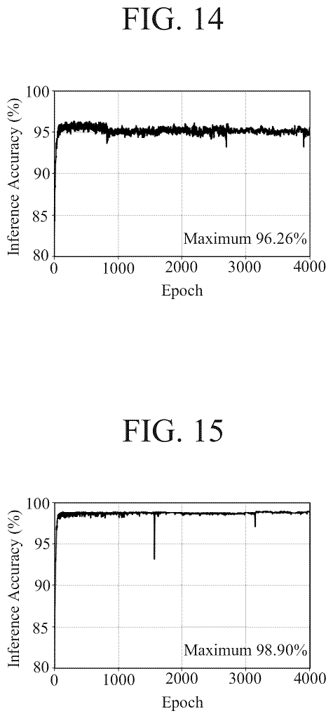

FIG. 14 is a graph illustrating an example (1) of a calculation result of inference accuracy by the information processing device 1 according to the first embodiment. In FIG. 11, the horizontal axis represents the number of iterations (epochs) when the graph neural network is trained using the training data, and the parameter of the graph neural network is updated. The vertical axis indicates inference accuracy of test data not used for training by the trained graph neural network.

As illustrated in FIG. 11, the inference accuracy for the test data is improved as the number of iterations increases, and the maximum inference accuracy is 96.26% in 4,000 iterations.

Note that the graph neural network used to calculate the inference result illustrated in FIG. 14 has a combination of 6 hidden layers and a rectified linear unit (ReLU), and the feature amounts obtained by the graph neural network and the ReLU are classified into any of nine types of outputs in two fully connected layers.

In addition, cross entropy was used as a loss function, and adaptive moment estimation (Adam) was used as an optimization function. The batch size was set to 500, and the graph neural network was trained so as to bring the loss function close to 0.

As described above, the inference accuracy by the trained graph neural network was about 90% by the training of the graph neural network only by the type of component and the connection relationship of each component.

Note that, when the circuits indicated by the test data were classified from the graph network by 77% of people without prejudice that they are power supply circuits, the human inference accuracy was around 50%.

From this result, it can be seen that the inference accuracy based on the present technique is significantly higher than that of a person.

FIG. 15 is a graph illustrating an example (2) of the calculation result of the inference accuracy by the information processing device 1 according to the first embodiment, and illustrates a result of training the graph neural network using a passive element, which is a node used in calculating the inference result of FIG. 14, to which a component constant is assigned as training data. The passive element is, for example, a resistor, a capacitor, or a coil. Since a dynamic range that a value of a passive element can take is large, a logarithm of a base of 10 was taken with respect to an identification number corresponding to the type of the passive element, the normalization was performed to make it equal to or more than 0 and equal to or less than 1, and the value is input as a real number.

For example, in a case where the node information is (C1, 0.33 uF) and (L2, 10 uH), and the identification numbers of C1 is 1 and the identification numbers of L2 is 2, the processing unit 12 converts them into (1, −6.48) and (2, −5.00), respectively. After all the conversions are completed, the processing unit 12 performs normalization processing using the maximum value and the minimum value, and inputs the normalized value to the graph neural network as node information. Information regarding the type of an active element (semiconductor) (for a power supply circuit, an operational amplifier circuit, or the like) was not input because it becomes the same as the correct answer data, and the component information of the active element was set to 0.

However, the component information of the active circuit need not be 0, and an appropriate component information may be selected.

In addition, GND, IN, and OUT were also set to 0 in the same manner as for the active element.

It was confirmed that the inference accuracy for the test data becomes 98.90% with the same number of iterations when the inference calculation is performed without changing the conditions other than the conditions when FIG. 14 is calculated.

By training of the graph neural network by the processing unit 12, it is possible to classify the circuit type only from link information. Note that common identification numbers are assigned to the semiconductor elements. When the type of the semiconductor element is the identification number, it matches the type of the circuit, and thus the inference accuracy becomes high without training the link information. Thus, information held by the semiconductor element is discarded, and information other than the semiconductor element is not included. The processing unit 12 updates the component names in the component name list and the combination list with the identification numbers assigned to the respective component names in this manner.

### Modification 2

The processing unit 12 may generate a new graph network by simultaneously training the generative network and the identification network in a generative adversarial network using, as training data, a dataset obtained by combining the graph network and correct answer data of characteristics of a plurality of electric circuits added respectively to the electric circuits, and inputting data indicating characteristics similar to the correct answer data to the generative network. By combining a graph neural network with a generative adversarial network, circuit diagrams can be generated from circuit specifications such as desired output signal waveforms.

The processing unit 12 simultaneously trains a generative network that is a neural network on a side generating a circuit (generator) and an identification network that is a neural network on a side determining a circuit (discriminator) in the generative adversarial network. Then, the processing unit 12 trains the graph neural network so as to increase the performance on the generation side and reduce the difference between a circuit serving as the teacher data or the output of the circuit and a circuit on the generation side or the output of the circuit. In this manner, input data can be created from the correct answer data. That is, when a requested design request is set as correct answer data, input data satisfying the correct answer data, that is, a combination of a node and an edge can be generated.

Furthermore, not only the output signal but also a plurality of pieces of data such as heat generation or component cost may be used as correct answer data to cause the generative adversarial network to train.

In this case, it is possible to generate a circuit that simultaneously optimizes a signal waveform flowing through each edge, heat generation at each node, power at each node, the cost of the entire circuit, or the like.

In addition, since the circuit can be designed in a short time, it is possible to review the required specifications or the cost at the initial design stage.

In order to create a specific waveform at a node that is a circuit component, a node whose characteristic or type is unknown may be given, the characteristic or type of the component may be predicted, and the waveform may be optimized.

Prediction of a characteristic of a component can be implemented by generating a node attribute in the graph neural network in the generative adversarial network.

The prediction of the type of component can be implemented by a technique of classifying nodes in the graph neural network.

In addition, a part of the type of the node that is the correct answer data of the training data is set as a black box, and the graph neural network is caused to train to predict the type of the node as self-supervised learning. This also makes it possible to predict the type of node using the trained graph neural network.

In addition, the information processing device 1 may train a graph neural network by using data for which calculation for a large-scale circuit diagram has been completed, and predict a voltage or a frequency characteristic of a voltage applied to the component by using the trained graph neural network.

This can be implemented by an existing technology of generating attribute information of a node in the graph neural network in the generative adversarial network. However, since it should not be contrary to Kirchhoff's law which is a physical constraint, it can be implemented by a constrained generative adversarial network.

Alternatively, a part of the voltage or the frequency characteristic of the voltage that is the correct answer data of the training data is set as a black box, and the graph neural network is caused to train to predict the voltage or the frequency characteristic of the voltage as self-supervised learning. This also makes it possible to predict the voltage or the frequency characteristic of the voltage using the trained graph neural network.

Furthermore, the information processing device 1 can create a circuit depending on a design purpose by predicting a connection between existing nodes in order to create a specific waveform for an edge to be a wiring in the circuit.

This corresponds to an edge prediction (link prediction) in a graph neural network, and after a graph network is created on the basis of the present embodiment, prediction can be performed using an existing technique using the graph neural network.

Alternatively, a part of the presence or absence of an edge between nodes, which is the correct answer data of the training data, is set as a black box, and the graph neural network is caused to train to predict the presence or absence of an edge between nodes as self-supervised learning. This also makes it possible to predict the presence or absence of an edge between nodes of an unknown circuit (graph network) using a trained graph neural network.

For example, by the graph neural network, it is also possible to predict a current to be applied to a component and frequency characteristic of the current using the graph neural network trained by using calculated results for a large-scale circuit diagram for which circuit simulation is difficult.

Specifically, similarly to the above-described case of generating the node attribute in the generative adversarial network, the processing unit 12 assigns a dataset obtained by combining the graph network and the correct answer data, which is a matrix having the feature amount obtained by assigning a voltage or a frequency characteristic of a voltage to each node in the graph network as an element of the node attribute, to the node as the training data. Then, as the generative adversarial network for predicting the voltage or the frequency characteristic of the voltage, a relationship between a graph network generated from a circuit diagram and the voltage or the frequency characteristic of the voltage may be trained by a graph neural network, and the graph neural network may be used to predict the voltage or the frequency characteristic of the voltage at a part or all nodes in the graph network not used for the training.

The generative adversarial network includes a generative network that hides a calculated result as training data and predicts the voltage or the frequency characteristic of the voltage, and an identification network that identifies the correctness of the generated prediction. In the generative adversarial network, the generative network and the identification network are simultaneously trained so as to reduce a difference between the identification result and a calculated result that is training data.

Alternatively, a part of a current and a frequency characteristic of a current, which are correct answer data of training data, is set as a black box, and the graph neural network is caused to train to predict the current and the frequency characteristic of the current as self-supervised learning. This also makes it possible to predict the current and the frequency characteristic of the current of an unknown circuit (graph network) using the trained graph neural network.

In addition, the processing unit 12 may train the graph neural network for predicting a type of a component using a dataset obtained by combining the graph network and data including a type of a component corresponding to each of the nodes in the graph network as training data, and predicts a type of a component that is a part or all of the nodes in the graph network not used for the training by using the graph neural network. This is to create a graph network in which input data of a graph neural network is created from a circuit diagram, and training data in which output data is set as a type of a component corresponding to a node, and perform supervised training using the training data as teacher data. This makes it possible to predict the type of component to be used for any graph network using the trained graph neural network.

Furthermore, the processing unit 12 may train the graph neural network for predicting a current or a frequency characteristic of a current at the edge using a dataset obtained by combining the graph network and correct answer data that is a matrix having a feature amount indicating the current or the frequency characteristic of the current at each of edges of the graph network as an element as training data, and predict the current or the frequency characteristic of the current at a part or all of the edges of the graph network not used for the training by using the graph neural network.

This is to create a graph network in which input data of the graph neural network is created from a circuit, and training data in which output data is set as a current or a frequency characteristic of a current corresponding to an edge, and to perform supervised learning using the training data as teacher data. This makes it possible to predict the current or the frequency characteristic of the current in any graph network using the trained graph neural network.

In addition, in a case where there is sufficient training data, it is possible to predict a current or a frequency characteristic of a current in any graph network using a generative adversarial network, self-supervised learning, or the like, similar to the above-described case of generating the node attribute in the generative adversarial network. Prediction of a current or a frequency characteristic of a current in any graph network can be implemented by methods such as supervised learning, generative adversarial network or self-supervised learning.

Here, the supervised learning is a dataset with few label errors, and is effective when the bias and the variance of the entire dataset are small. A generative adversarial network is effective when the dataset is large and a solution as a solution to an inverse problem is required, such as when optimization of the entire circuit is performed. The self-supervised learning is effective in a case where it is difficult to assign a label, a case where there are many label errors, or a case where more abundant calculation resources can be obtained because of a large amount of calculation.

In addition, a result of the graph neural network obtained by self-supervised learning, that is, a weight matrix obtained by training may be subjected to transfer learning or fine-tuning, and may be used in combination, for example, supervised learning which is a problem with an insufficient dataset. As described above, the information processing device 1 may change the structure or training method of the graph neural network, the way of giving the teacher data, and the like according to the given condition or the obtained result.

Furthermore, the processing unit 12 may train the graph neural network for predicting power or a frequency characteristic of power in at least one of a node or an edge using a dataset obtained by combining the graph network and correct answer data that is a matrix having a feature amount indicating the power or the frequency characteristic of the power in at least one of a part or all of nodes or edges included in the graph network as an element as training data, and predict the power or the frequency characteristic of the power in at least one of a part or all of nodes or edges included in the graph network not used for the training by using the graph neural network.

Also in this case, supervised learning of a graph neural network is performed with an input as a graph network and an output as power or a frequency characteristic of power. The power or the frequency characteristic of the power can be inferred by the unknown input of the trained graph neural network obtained as a result.

In addition, the input is a graph network, the power or the frequency characteristic of the power is predicted from the generative network, and the graph neural network is trained so as to reduce the difference between the prediction result and the correct answer data in the identification network. The power or the frequency characteristic of the power can be inferred by the unknown input of the trained graph neural network obtained as a result.

Furthermore, self-supervised learning of the graph neural network is performed in which an input is a graph network, and an output is trained to hide a part of power or a frequency characteristic of power and predict a hidden value. The power or the frequency characteristic of the power can be inferred by the unknown input of the trained graph neural network obtained as a result.

Conventionally, even in prediction calculation that requires a long time, it is possible to predict an output in real time without passing through a circuit simulator by using inference by the graph neural network. For example, by roughly performing inference using the graph neural network and then interpolating prediction by calculation of a circuit simulator, the number of times of use of the circuit simulator that requires prediction calculation time and calculation cost can be reduced. Furthermore, a result calculated using the circuit simulator or a result actually measured may be used again as teacher data.

### Modification 3

In Modification 3, it will be described that the wiring can have a current direction, the component name list can have a voltage of a specific frequency or a frequency characteristic of a voltage, and the combination list can have a current of a specific frequency or a frequency characteristic of a current.

In the direction of the current, the following combination list is obtained from the netlist of the electric circuit illustrated in FIG. 6.
(1); (IN,A)
(2); (A,B)
(3); (B,C),(C,D),(D,B)
(4); (D,OUT)
G-A; (GND,A)
G-B; (GND,B)
G-C; (GND,C)

For example, in (IN,A), in consideration of the writing order, when (IN,A) is written, it can be defined as the direction of the current from the IN terminal to the A terminal.

Applying the component name list and the wiring name list to graph theory, the component name list is a node, and the wiring name list is an edge. When the direction of the current is not considered, the graph network becomes an undirected graph.

On the other hand, by defining the writing order, the graph network can be considered as a directed graph. Note that, in the case of a circuit including an alternating current, the direction of the current cannot be correctly defined only by the circuit diagram.

In the case of a directed graph, it is possible to grasp the direction of the current from a time difference of arrival by bringing the circuit into an operating state by circuit simulation or actual measurement, superimposing pulsed signals that do not affect this operation, and simultaneously observing a plurality of points on the wiring to be measured with a voltage probe or a current probe. However, in the circuit simulation, detection is difficult because no time difference occurs on the wiring.

In this case, the processing unit 12 virtually arranges a small inductance of about a residual inductance (about 1 nH/mm) of the wiring on the wiring, and can estimate the direction of the current from the voltage at both ends of the inductance or the time difference of changes in the current.

In addition, in communication, signals may flow bidirectionally. In such a case, by including not only (A, B) but also (B, A) in the combination list, it is possible to perform processing as if signals flow bidirectionally.

In graph theory, a combination list can be defined as an adjacency matrix.

In order to form the adjacency matrix, a square matrix having the same number of rows and columns as the maximum value of the elements of the combination list is prepared, the rows and columns of the square matrix are made to correspond to the combination list, for example, 1 is input to the corresponding part, and all the non-corresponding components are set to 0, whereby an adjacency matrix can be created.

For example, when (5,3) is included in the combination list, an adjacency matrix can be created by setting 5 rows and 3 columns to 1. When the flow of the current in the electric circuit is not considered, this adjacency matrix is a symmetric matrix, and thus, when (5,3) is in the combination list, 1 is input in 5 rows and 3 columns and 3 rows and 5 columns.

On the other hand, when the direction of the current in the circuit is taken into consideration, only one of five rows and three columns and three rows and five columns is set to 1, and the other is set to 0. As a result, a symmetric matrix is obtained when the direction of the current is not considered, whereas an asymmetric matrix is obtained when the direction of the current is considered.

In both the case of not considering the direction of the current and the case of considering the direction of the current, the adjacency matrix is an upper triangular matrix or a lower triangular matrix.

In particular, since there is no self-loop in the second embodiment described later, the adjacency matrix is an upper triangular matrix in which the diagonal components are 0 or a lower triangular matrix in which the diagonal components are 0.

However, in a case where there is even one signal in a circuit that performs both reception and transmission by one wiring, such as bidirectional, that is, an antenna or a communication signal, in the circuit, the upper triangular matrix or the lower triangular matrix is not formed, but an asymmetric matrix is formed.

Further, in the component name list, a voltage of a specific frequency or a frequency characteristic of a voltage in the electric circuit can be set similarly to a component constant or the like.

When the frequency characteristic is set in the component name list, it is necessary to convert the frequency characteristic into a discrete value and input a signal as an amplitude at a discrete frequency.

For example, in a case where it is desired to input frequency characteristics of 1 MHz to 10 MHz, 10 elements attached to each component only needs to be set in increments of 1 MHz.

In this case, the matrix is set as a matrix having the same number of rows as the number of components and the number of columns for each frequency increment (10 columns in increments of 1 MHz from 1 MHz to 10 MHz).

However, it is necessary to set the frequency band or the increments to the same conditions for all the circuit diagrams used for processing and all the components in the circuit diagrams.

Note that, although increments of 1 MHz from 1 MHz to 10 MHz are illustrated, as long as the increments are common to all the components, the increments of frequency may be any increment such as logarithm, and may not be uniform.

Furthermore, the order of the frequencies may be different, and the component name list may be configured as one matrix by combining in such a manner that the identification number and the frequency characteristic defined by the type of the component, the model number of the component, or the like are different columns.

Furthermore, a current of a specific frequency or a frequency characteristic of a current can be given to the combination list. Also in this case, it can be considered similarly to the frequency characteristic of the voltage.

The combination list can be input as a matrix in which the vertical axis has rows corresponding to the number of combinations in the combination list and the horizontal axis has columns corresponding to the number of frequency increments (10 columns in increments of 1 MHz from 1 MHz to 10 MHz) as long as the frequency bands and the frequencies are the same for all the circuit diagrams and all the wirings.

However, the combination list is meaningful to the combination itself, and it is not desirable to add current information to the combination list in the same manner as the component name list. Thus, it is desirable that these frequency characteristics are defined as a single matrix and added to the combination list as attribute information (edge attribute in graph theory) of the wiring.

Since the combination list has rows corresponding to the number of combinations, the combination list can also be used for a directed graph, and even in a case where the frequency characteristics of the outgoing current are different from the frequency characteristics of the incoming current, they can be processed as being different.

In addition, in the combination list, information other than the current or the frequency characteristic of the current, for example, the length of the wiring line or the thickness of the wiring line may be input to the single matrix as information of different columns.

As described above, the information processing device 1 according to the first embodiment includes the acquisition unit 11 to acquire a netlist of an electric circuit, and the processing unit 12 to extract a component name list and a wiring name list from the netlist, and create the component name list that is updated by adding component names indicating a ground terminal, an input terminal, and an output terminal, the wiring name list that is updated by removing wiring names indicating a ground wiring, an input wiring, and an output wiring, and the combination list including an extracted component name obtained by extracting a component name corresponding to a wiring name in the updated wiring name list from the component names in the updated component name list, and output the updated component name list and the combination list.

In this manner, the information processing device 1 can provide list information in which information deterioration caused by converting an electric circuit into a graph network can be suppressed.

An information processing device 1 according to the first embodiment includes an acquisition unit 11 to acquire a netlist of an electric circuit, and a processing unit 12 to extract a component name list and a wiring name list from the netlist, and create a component name list that is updated by adding component names indicating a ground terminal, an input terminal, and an output terminal, a wiring name list that is updated by removing wiring names indicating a ground wiring, an input wiring, and an output wiring, and a combination list including an extracted component name obtained by extracting a component name corresponding to a wiring name in the updated wiring name list from the component names in the updated component name list and a wiring name corresponding to the extracted component name, and output the updated component name list and the combination list.

In this manner, the information processing device 1 can provide list information in which information deterioration caused by converting an electric circuit into a graph network can be suppressed. Furthermore, since the information processing device 1 can suppress an increase in the number of combinations of components, it is possible to reduce an increase in the calculation amount and the calculation time required for the processing of the graph neural network using the list information including the combination list.

In the information processing device 1 according to the first embodiment, the processing unit 12 outputs the updated component name list and combination list in which component names are replaced with unique identification numbers for respective features of components. Thus, the information processing device 1 can reduce the amount of information by expressing the list information with a numerical value, and can prevent information deterioration that occurs when the list information is converted into the graph network. This is because, when the definition obtained by converting the feature of the component into a numerical value is used in reverse, the feature of the component can be determined from the numerical value, that is, the feature of the component and the numerical value are bijective.

In the information processing device 1 according to the first embodiment, the processing unit 12 defines a unique identification number for each type of component. Thus, the information processing device 1 can reduce the amount of information by expressing the list information with a numerical value, and can prevent information deterioration that occurs when the list information is converted into the graph network. This is because, when the definition obtained by converting the type of component into a numerical value is used in reverse, the type of component can be determined from the numerical value, that is, the type of component and the numerical value are bijective.

In the information processing device 1 according to the first embodiment, the processing unit 12 defines the unique identification number for each of model numbers of components. Thus, the information processing device 1 can reduce the amount of information by expressing the list information with a numerical value, and can prevent information deterioration that occurs when the list information is converted into the graph network. This is because, when the definition obtained by converting the model number of the component into a numerical value is used in reverse, the model number of the component can be determined from the numerical value, that is, the type of the component and the numerical value are bijective.

In the information processing device 1 according to the first embodiment, the processing unit 12 replaces a component name in the component name list with a row or a column of a feature amount matrix obtained by one-hot expression of a feature of the component. Thus, the information processing device 1 can calculate the component name in the component name list and the feature of the component in a matrix. This is because, when the definition obtained by converting the feature of the component into the one-hot vector representation is used in reverse, the feature of the component can be determined from the one-hot vector representation.

In the information processing device 1 according to the first embodiment, in a case where the electric circuit includes two or more semiconductors, the processing unit 12 changes the element corresponding to the semiconductor in the feature amount matrix to a different value for each semiconductor. Thus, the information processing device 1 can prevent information deterioration that occurs when the list information is converted into the graph network. This is because the semiconductor can be determined from the element corresponding to the semiconductor by inversely using the definition obtained by converting the semiconductor into the element corresponding to each semiconductor.

In the information processing device 1 according to the first embodiment, the processing unit 12 replaces an element corresponding to a passive circuit in the feature amount matrix with a function value calculated by substituting a circuit constant of a component into a function including a logarithm. Thus, the information processing device 1 can reduce the amount of information by expressing the list information with a numerical value, and can prevent information deterioration that occurs when the list information is converted into the graph network. This is because the circuit constant is a real number larger than 0 and has a bijective relationship with the function including the logarithm, so that the numerical value of the original circuit constant can be calculated from the numerical value after the function is performed from the function including the logarithm.

In the information processing device 1 according to the first embodiment, the processing unit 12 performs both or one of normalization and standardization on the function value. Thus, the information processing device 1 can reduce the amount of information by expressing the list information with a numerical value, and can prevent information deterioration that occurs when the list information is converted into the graph network. This is because, also in normalization or standardization, the value before normalization or standardization and the value after normalization or standardization are bijective and thus can be bidirectionally converted.

In the information processing device 1 according to the first embodiment, in a case where there are three or more combinations of component names corresponding to one wiring name in the combination list, the processing unit 12 decomposes each of the combinations into two combinations. Thus, the information processing device 1 can easily create the adjacency matrix of the graph network from the combination list.

In the information processing device 1 according to the first embodiment, in a case where the combination list has three or more component names, the processing unit 12 decomposes the combination list into lists having two component names.

Thus, the information processing device 1 can prevent information deterioration that occurs when the list information is converted into the graph network.

In the information processing device 1 according to the first embodiment, the acquisition unit 11 acquires each of the netlists of two or more electric circuits. The processing unit 12 extracts a component name list from each of the netlists, combines the extracted component name list into one component name list, and removes duplicate component names from the combined one component name list. Thus, the information processing device 1 can suppress an increase in the information amount of the component name list.

In the information processing device 1 according to the first embodiment, the component name list is a node in a graph network, the wiring name list is an edge in the graph network, and the combination list is an adjacency matrix in the graph network. Thus, the information processing device 1 can use the list information as a graph network.

In the information processing device 1 according to the first embodiment, the processing unit 12 refers to a database including a semiconductor as a noise source and a terminal number of the semiconductor, performs a search process of continuously searching for adjacent components from the electric circuit with a terminal corresponding to the terminal number as a starting point under a condition that the same component is not passed twice or more, extracts a current loop representing the semiconductor, and terminates the search process. In this manner, the information processing device 1 can search for a semiconductor, a capacitor, a coil, a ground, and a semiconductor loop path.

In the information processing device 1 according to the first embodiment, the processing unit 12 determines whether or not there is a component indicating a noise filter in the current loop. Thus, the information processing device 1 can extract a noise filter provided in a current loop that is a path through which a current flows.

In the information processing device 1 according to the first embodiment, the processing unit 12 extracts a feature of a semiconductor to be searched for and a feature of a current loop indicating the semiconductor from one or a plurality of electric circuits including one or more semiconductors, and searches for a semiconductor similar to the semiconductor to be searched for using the extracted feature of the semiconductor and the feature of the current loop. In this manner, the information processing device 1 can search for similar circuits.

In the information processing device 1 according to the first embodiment, the processing unit 12 extracts the combination list according to a direction in which a current flows, and generates an adjacency matrix of an asymmetric matrix from the extracted combination list. In this manner, the information processing device 1 can also suppress the occurrence of information deterioration in a circuit in which the direction of current flow is known.

In the information processing device 1 according to the first embodiment, the processing unit 12 sets an amplitude of the current to a real number between the components connected to each other, and sets an amplitude of the current to 0 between wirings not connected to each other in the adjacency matrix. In this manner, the information processing device 1 can also suppress the occurrence of information deterioration in a circuit in which the direction of current flow is known.

In the information processing device 1 according to the first embodiment, the processing unit 12 sets a combination of a node and an edge as input data of a graph neural network. Thus, the information processing device 1 can train a graph neural network using the graph network.

In the information processing device 1 according to the first embodiment, the processing unit 12 trains the graph neural network for classifying the electric circuit using a dataset obtained by combining the graph network and circuit classification data assigned to each of the plurality of electric circuits as training data, and inputs the graph network not used for the training to the graph neural network to classify the electric circuit. In this manner, the information processing device 1 can classify the electric circuits.

In the information processing device 1 according to the first embodiment, the processing unit 12 simultaneously trains a generative network and an identification network in a generative adversarial network using a dataset obtained by combining the graph network and correct answer data of a characteristic of each of the plurality of electric circuits as training data, and inputs data indicating a characteristic similar to the correct answer data to the generative network to generate the graph network that is new.

In this manner, the information processing device 1 can automatically design an electric circuit corresponding to a new graph network.

In the information processing device 1 according to the first embodiment, the processing unit 12 trains the graph neural network for predicting a voltage or a frequency characteristic of a voltage to be applied to a node by using a dataset obtained by combining the graph network and correct answer data that is a matrix having a feature amount obtained by applying a voltage or a frequency characteristic of a voltage to each of nodes in the graph network as an element as training data, and predicts the voltage or the frequency characteristic of the voltage in a part or all of nodes in the graph network not used for the training by using the graph neural network. In this manner, the information processing device 1 can predict the output voltage of the unknown circuit or the frequency characteristic of the output voltage without executing the circuit simulation.

In the information processing device 1 according to the first embodiment, the processing unit 12 trains the graph neural network for predicting a type of a component using a dataset obtained by combining the graph network and data including a type of a component corresponding to each of nodes in the graph network as training data, and predicts a type of a component that is a part or all of nodes in the graph network not used for the training by using the graph neural network. In this manner, the information processing device 1 can predict the type of component.

In the information processing device 1 according to the first embodiment, the processing unit 12 trains the graph neural network for predicting a current or a frequency characteristic of a current at the edge using a dataset obtained by combining the graph network and correct answer data that is a matrix having a feature amount indicating the current or the frequency characteristic of the current at each of edges of the graph network as an element as training data, and predicts the current or the frequency characteristic of the current at a part or all of the edges of the graph network not used for the training by using the graph neural network.

In this manner, the information processing device 1 can predict the output current or the frequency characteristic of the output current of the unknown circuit without executing the circuit simulation.

In the information processing device 1 according to the first embodiment, the processing unit 12 trains the graph neural network for predicting power or a frequency characteristic of power in at least one of a node or an edge using a dataset obtained by combining the graph network and correct answer data that is a matrix having a feature amount indicating the power or the frequency characteristic of the power in at least one of a part or all of nodes or edges included in the graph network as an element as training data, and predicts the power or the frequency characteristic of the power in at least one of a part or all of nodes or edges included in the graph network not used for the training by using the graph neural network. In this manner, the information processing device 1 can predict the output power or the frequency characteristic of the output power of the unknown circuit without executing the circuit simulation.

In the information processing device 1 according to the first embodiment, the processing unit 12 trains the graph neural network for predicting the presence or absence of an edge between nodes in the graph network using the graph network as training data, and predicts presence or absence of an edge between nodes in the graph network not used for the training by using the graph neural network.

In this manner, the information processing device 1 can predict the presence or absence of an edge between nodes in a graph network that is not used for training.

In the information processing device 1 according to the first embodiment, the processing unit 12 trains a graph neural network for clustering a finite number of electric circuits depending on characteristics thereof using the graph network as training data, and classifies the electric circuits into similar electric circuit groups by clustering graph networks not used for training using the graph neural network. In this manner, the information processing device 1 can classify similar electric circuit groups.

An information processing method according to the first embodiment includes executing, by an information processing device 1, acquiring a netlist of an electric circuit, extracting a component name list and a wiring name list from the netlist, creating a component name list that is updated by adding component names indicating a ground terminal, an input terminal, and an output terminal, creating a wiring name list that is updated by removing wiring names indicating a ground wiring, an input wiring, and an output wiring, extracting a component name corresponding to a wiring name in the updated wiring name list from the component names in the updated component name list, and creating a combination list including an extracted component name, and outputting the updated component name list and the combination list. In this manner, it is possible to provide list information in which information deterioration caused by converting an electric circuit into a graph network can be suppressed.

An information processing method according to the first embodiment includes executing, by an information processing device 1, acquiring a netlist of an electric circuit, extracting a component name list and a wiring name list from the netlist, creating a component name list that is updated by adding component names indicating a ground terminal, an input terminal, and an output terminal, creating a wiring name list that is updated by removing wiring names indicating a ground wiring, an input wiring, and an output wiring, extracting a component name corresponding to a wiring name in the updated wiring name list from the component names in the updated component name list, and creating a combination list including an extracted component name and a wiring name corresponding to the extracted component name, and outputting the updated component name list and the combination list. In this manner, it is possible to provide list information in which information deterioration caused by converting an electric circuit into a graph network can be suppressed. Furthermore, since an increase in the number of combinations of components can be suppressed, an increase in the calculation amount and the calculation time required for the processing of the graph neural network using the list information including the combination list can be reduced.

### Second Embodiment

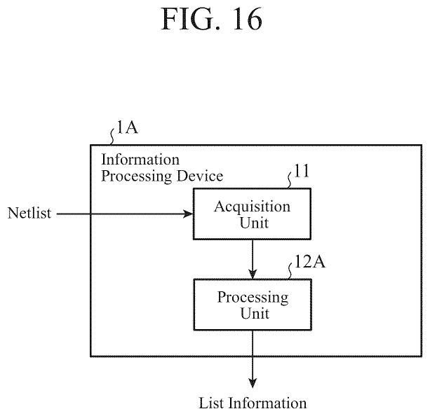

FIG. 16 is a block diagram illustrating a configuration example of an information processing device 1A according to a second embodiment. In FIG. 16, the information processing device 1A acquires a netlist of an electric circuit, and provides list information in which information deterioration that occurs when the electric circuit is converted into a graph network using the acquired netlist can be suppressed. The graph network of the electric circuit is information representing the electric circuit using a node representing a component and an edge representing a wiring line. The graph network also includes information indicating a feature amount of the node and a feature amount of the edge.

As illustrated in FIG. 16, the information processing device 1A includes an acquisition unit 11 and a processing unit 12A.

The acquisition unit 11 executes a first process of acquiring a netlist of the electric circuit. For example, the information processing device 1 is connected to a computer equipped with circuit design CAD, and the acquisition unit 11 acquires a netlist created using the circuit design CAD from the computer.

In addition, the acquisition unit 11 may acquire a circuit diagram model of an electric circuit operating in a circuit simulator and convert the circuit diagram indicated by the circuit diagram model into a netlist.

That is, the acquisition of the netlist by the acquisition unit 11 includes acquiring the netlist by converting the circuit diagram.

The processing unit 12A adds, to the updated component name list, a component name indicating a two-terminal component by regarding a component connected to three or more wirings as the number of two-terminal components equal to the number of wirings by using a component name list updated by adding component names indicating a ground terminal, an input terminal, and an output terminal and a wiring name list updated by removing wiring names indicating a ground wiring, an input wiring, and an output wiring, removes a component name indicating a component before being regarded as the two-terminal component from the updated component name list, connects the three or more wirings to one terminal of the two-terminal component, connects other terminals of the two-terminal component by a new wiring, adds a wiring name indicating the new wiring to the updated wiring name list, extracts a component name corresponding to a wiring name in the updated wiring name list from the updated component name list, creates the combination list including the extracted component name, and outputs the updated component name list and the combination list. In addition, the processing unit 12A may output an updated component name list and combination list in which component names are replaced with identification numbers.

The information processing device 1A is, for example, a computer connected to an information network.

The computer may be a server or client that can be connected to a cloud or the like via an information network, or may be a stand-alone computer that is not connected to the information network. It may also be a computer used in a closed network environment in a factory called edge computing.

Furthermore, the information processing device 1A may be a smartphone, a tablet terminal, a PC, or a microcomputer.

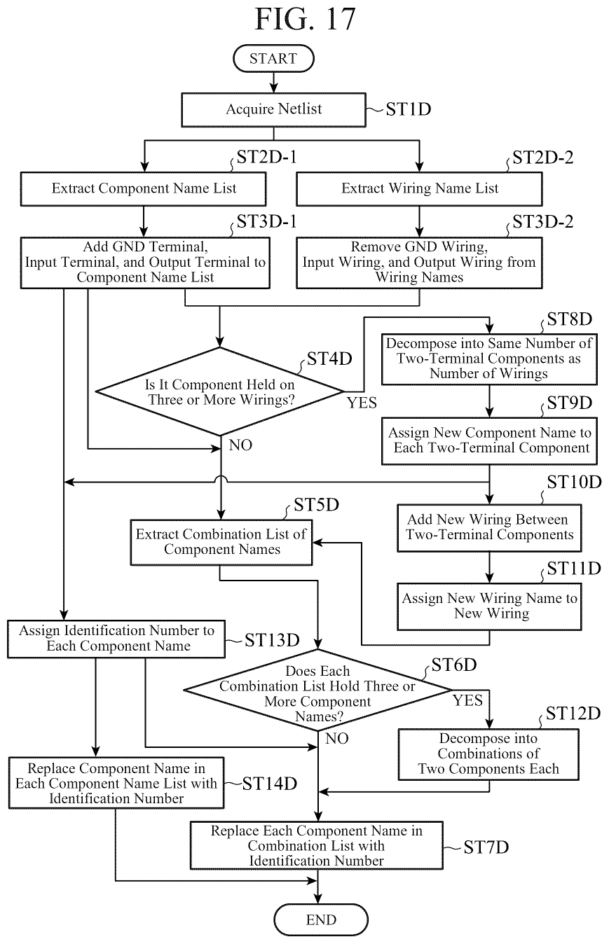

FIG. 17 is a flowchart illustrating an information processing method according to the second embodiment, and illustrates a series of operations by the information processing device 1A. The acquisition unit 11 acquires the netlist (step ST1D). The processing unit 12A extracts a component name list from the netlist (step ST2D-1), and extracts a wiring name list from the netlist (step ST2D-2).

For example, the processing unit 12A stores all the component names included in the netlist in the component name list, and stores all the wiring names included in the netlist in the wiring name list.

Note that either the processing of step ST2D-1 or the processing of step ST2D-2 may be executed first, or may be executed simultaneously.

The processing unit 12A adds the ground wiring, the input wiring, and the output wiring included in the netlist to the component name list as a ground terminal, an input terminal, and an output terminal (step ST3D-1). The processing unit 12A removes the ground wiring, the input wiring, and the output wiring from the wiring name list (step ST3D-2). Thus, information indicating the ground terminal, the input terminal, and the output terminal remains in the component name list as component information, so that it is possible to suppress information deterioration when the electric circuit is converted into the graph network using the list information including the component name list. Note that either the processing of step ST3D-1 or the processing of step ST3D-2 may be executed first, or may be executed simultaneously.

The processing unit 12A determines whether or not there is a component connected to three or more wirings using the component name list and the wiring name list (step ST4D). When there is no component connected to three or more wirings (step ST4D; NO), the processing proceeds to step ST5D. In FIG. 17, processing of step ST5D, step ST6D, step ST7D, step ST12D, step ST13D, and step ST14D is similar to that of step ST4, step ST5, step ST6, step ST7, step ST8, and step ST9 in FIG. 5, and thus description thereof is omitted.

If there are components connected to three or more wirings (step ST4D; YES), the processing unit 12A regards the components connected to three or more wirings as a number of two-terminal components equal to the number of wirings (step ST8D). Subsequently, the processing unit 12A assigns a new component name to the two-terminal component (step ST9D). Then, the processing unit 12A connects three or more wirings to one terminal of the two-terminal component, and connects the other terminals of the two-terminal component to each other by adding a new wiring (step ST10D). The processing unit 12A adds the wiring name assigned to the new wiring to the wiring name list (step ST11D).

In this manner, the processing unit 12A connects the two-terminal components disassembled from one component, and gives a new wiring name to the wiring used for each connection. Since there is a number of other terminals of each of the two-terminal components equal to the number of three or more wirings, respective terminals and the wirings are connected. By performing the conversion in this manner, it is possible to prevent a self-loop or multiple sides, and it is possible to prevent information deterioration at the time of conversion from the electric circuit to the graph network and conversion from the graph network to the electric circuit.

For example, a self-loop occurs when wiring is performed from a terminal of a semiconductor to a different terminal of the same semiconductor without passing through a circuit component, but such wiring may be necessary to define the operation of the semiconductor, and occurs in such a case. In the first embodiment, information deterioration occurs because such a condition is discarded, but by dividing into two-terminal components as in the second embodiment, conversion into a graph network can be performed while holding such information.

In addition, multiple sides are generated when a bus is wired from one semiconductor to another semiconductor in the case of having a plurality of input terminals in order to secure a current capacity by a power supply or the like.

Even in this case, in the first embodiment, such a condition is discarded, and thus information deterioration occurs, but by dividing such information into two-terminal components as in the second embodiment, conversion into a graph network can be performed while holding such information.

Similarly to the first embodiment, a component name held by each wiring name is extracted from the wiring name list updated in step ST11D, and a combination list of component names is extracted.

Similarly to the first embodiment, in a case where one wiring name holds three or more component names, one wiring is disassembled into a combination of two components.

In addition, an identification number is assigned to each component name using the updated component name list, and the identification number is replaced with an identification number corresponding to each component name in the combination list using the identification number.

Further, the component name list is replaced with an identification number, the component name list replaced with the identification number and the combination list replaced with the identification number is output, and the processing is completed.

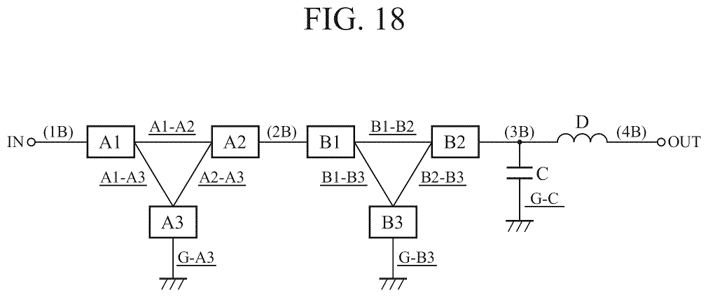

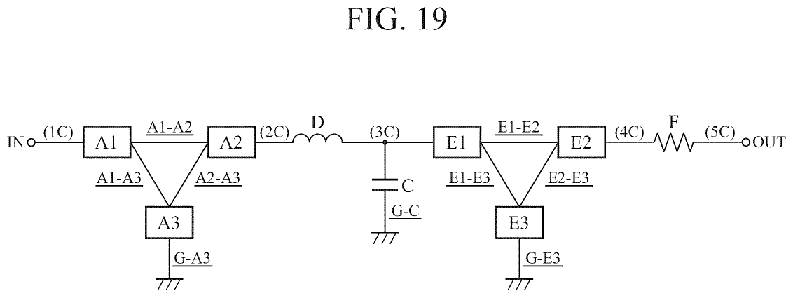

FIG. 18 is a circuit diagram illustrating an example (4) of the electric circuit. FIG. 19 is a circuit diagram illustrating an example (5) of the electric circuit. In FIG. 18, in a component A, three wirings (1) between an input terminal “IN” and the component A, (2) between a component B and the component A, and between GND and the component A are connected. The component A is disassembled into three two-terminal components, each of which is named A1, A2, A3, for example. In order to connect one terminal of the disassembled components to a terminal of the other disassembled components, A1 and A2, A2 and A3, and A3 and A1 are connected. Each is named as, for example, A1-A2, A1-A3, and A2-A3. The name G-A3 is also given between A3 and GND. Similarly, the component B is disassembled, and the disassembled components and the wiring between the components are given names, so that the electric circuit has the structure illustrated in FIG. 18.

The same applies to FIG. 19, and since the components holding three or more wirings in FIG. 18 are the component A and the component E, each of the components is disassembled, and a name is given to the wiring between the disassembled components. Note that, although the circuit diagram has been set as a processing target for simplicity of description, a netlist can be processed in a similar manner.

The netlist described in the first embodiment will be described below. When the component A is searched for in the #wiring in the netlist, it can be seen that the component A is held by the wiring of (1), (2), and GND.

Thus, it can be determined that three wirings are connected to the component A, and the component A can be disassembled into a two-terminal component.
#component
A
B
C
D
#wiring
(1); IN,A
(2); A,B
(3); B,C,D
(4); D,OUT
GND; A,B,C

As illustrated in FIG. 18, by disassembling the component into two-terminal components, the component name list becomes “A1, A2, A3, B1, B2, B3, C, D, GND, IN, OUT”, and the wiring name list becomes “(1), (2), (3), (4), A1-A2, A2-A3, A1-A3, B1-B2, B2-B3, B1-B3, G-A3, G-B3, G-C”.

Similarly to the first embodiment, the processing unit 12A adds “IN”, “OUT”, and “GND” to the component name list, and removes “IN”, “OUT”, and “GND” from the wiring name list.

Similarly, by disassembling components into two-terminal components as illustrated in FIG. 19, the component name list is “A1, A2, A3, C, D, E1, E2, E3, F, GND, IN, OUT”, and the wiring name list is “(1A), (2A), (3A), (4A), (5A), A1-A2, A2-A3, A1-A3, E1-E2, E2-E3, E1-E3, G-A3, G-E3, G-C”.

For the components of three or more terminals, the combination list of the electric circuits illustrated in FIG. 18 is as follows according to the combination list created from the updated wiring name list and the combination list of the two-terminal components. (1) to (4), G-C, G-A3, and G-B3 are created from a netlist, and A1-A2, A1-A3, A1-A3, B1-B2, B2-B3, and B1-B3 are combination lists created from an updated wiring name list.
(1); IN,A1
(2); A2,B1
(3); B2,C,D
(4); D,OUT
A1-A2; A1,A2
A2-A3; A2,A3
A1-A3; A1,A3
B1-B2; B1,B2
B2-B3; B2,B3
B1-B3; B1,B3
G-A3; GND,A3
G-B3; GND,B3
G-C; GND,C

Similarly, the following combination list can be extracted also for the circuit diagram illustrated in FIG. 19.
(1A); IN,A1
(2A); A2,D
(3A); D,C,E1
(4A); E2,F
(5A); F,OUT
A1-A2; A1,A2
A2-A3; A2,A3
A1-A3; A1,A3
E1-E2; E1,E2
E2-E3; E2,E3
E1-E3; E1,E3
G-A3; GND,A3
G-E3; GND,E3
G-C; GND,C

After the circuit components having three or more terminals are disassembled as described above, the structure is similar to that of the first embodiment.

The component name list related to the circuit illustrated in FIG. 18 is “A1, A2, A3, B1, B2, B3, C, D, GND, IN, OUT”, and the component name list related to the circuit illustrated in FIG. 19 is “A1, A2, A3, C, D, E1, E2, E3, F, GND, IN, OUT”. When these two are combined and the overlap is removed, “A1, A2, A3, B1, B2, B3, C, D, E1, E2, E3, F, GND, IN, OUT” is obtained. When a different identification number is assigned to each component name, the combined list is as follows, for example.
A1→1
A2→2
A3→3
B1→4
B2→5
B3→6
C→7
D→8
E1→9
E2→10
E3→11
F→12
GND→13
IN→14
OUT→15

When the identification numbers are used, the component name list related to the circuit illustrated in FIG. 18 is “1, 2, 3, 4, 5, 6, 7, 8, 13,14, 15”, and the component name list related to the circuit illustrated in FIG. 19 is “1, 2, 3, 7, 8, 9, 10,11,12,13,14, 15”.

In addition, also in the combination list, a combination list regarding the circuit illustrated in FIG. 18 is as follows by decomposing a combination having three or more component names into two and replacing each component name with an identification number.
(1); (14,1)
(2); (2,4)
(3); (5,7),(7,8),(8,5)
(4); (8,15)
A1-A2; (1,2)
A2-A3; (2,3)
A1-A3; (1,3)
B1-B2; (4,5)
B2-B3; (5,6)
B1-B3; (4,6)
G-A3; (13,3)
G-B3; (13,3)
G-C; (13,7)

Furthermore, the combination list regarding the circuits illustrated in FIG. 19 is as follows.
(1A); (15,1)
(2A); (2,8)
(3A); (8,7)(8,9),(7,9)
(4A); (10,12)
(5A); (12,15)
A1-A2; (1,2)
A2-A3; (2,3)
A1-A3; (1,3)
E1-E2; (9,10)
E2-E3; (10,11)
E1-E3; (9,11)
G-A3; (13,3)
G-E3; (13,11)
G-C; (13,7)

As an output result of the processing unit 12A, the component name list related to the circuit illustrated in FIG. 18 is “1, 2, 3, 4, 5, 6, 7, 8, 13, 14, 15”, and the combination list is “(14,1) (2,4) (5,7) (7,8) (8,5) (8,15) (1,2) (2,3) (1,3) (4,5) (5,6) (4,6) (13,3) (13,3) (13,7)”. In addition, the component name list related to the circuit illustrated in FIG. 19 is “1, 2, 3, 7, 8, 9, 10, 11, 12, 13, 14, 15”, and the combination list is “(15,1) (2,8) (8,7) (8,9), (7,9) (10,12) (12,15) (1,2) (2,3) (1,3) (9,10) (10,11) (9,11) (13,3) (13,11) (13,7)”.

In a component of a circuit, particularly a semiconductor, an operation may be controlled by short-circuiting one terminal of the semiconductor and a different terminal of the same semiconductor by wiring. The electric circuit having this structure has a self-loop in which the wiring comes out of itself and returns to itself.

However, it is possible to create a combination list from the netlist related to the electric circuit having the self-loop, but it is not possible to convert the combination list having the self-loop into the original netlist. This is because information deterioration occurs when the netlist is converted into the combination list. On the other hand, it is possible to eliminate the wiring that becomes the self-loop by performing the decomposition into the components of three or more elements as described above. Thus, the information processing device 1A according to the second embodiment can create a combination list regarding an electric circuit not having a self-loop by using a netlist regarding an electric circuit having a self-loop. As a result, the combination list can be converted into the netlist without causing information deterioration.

For example, in an electric circuit to which a power supply having a large amount of current is connected, wiring connected to the same power supply may be connected to a plurality of terminals of a semiconductor to disperse the current.

Further, there is an electric circuit having a semiconductor in which a power supply for pull-up or a signal for control is connected to a plurality of terminals.

Since these connection relationships are multiple sides, in a case where the multiple sides are included in the combination list, information of each side is not left and the combination list cannot be returned to the netlist, similarly to the self-loop. Thus, it is considered that information deterioration has occurred.

On the other hand, in the information processing device 1A according to the second embodiment, even an electric circuit having multiple sides can return the combination list to the original netlist. Thus, it is possible to convert the netlist into the combination list and inversely convert the combination list into the netlist without causing information deterioration.

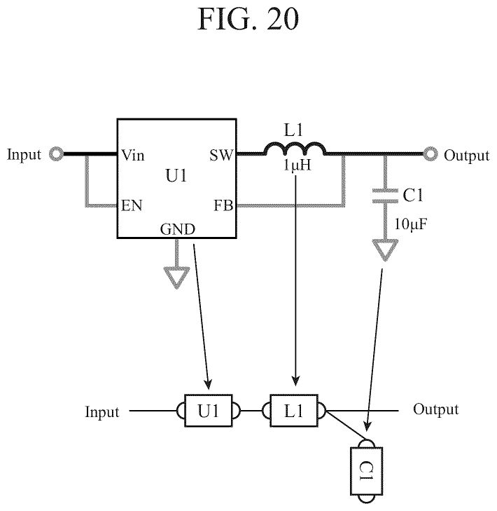

FIG. 20 is a schematic diagram illustrating an example (1) of an electric circuit and a graph network in the second embodiment. The electric circuit illustrated in FIG. 20 includes a switching power supply U1, and when a voltage is applied between the input terminal and the ground GND, a different voltage is output between the output terminal and the ground GND. A result of extracting the component list and the combination list from the netlist related to the electric circuit is referred to as a graph. In the electric circuit illustrated in FIG. 20, the graph cannot be converted into a circuit diagram. In particular, since the information of the wiring lines illustrated in gray in the circuit diagram in the upper part of FIG. 20 is missing, it is considered that information deterioration has occurred when the graph is converted.

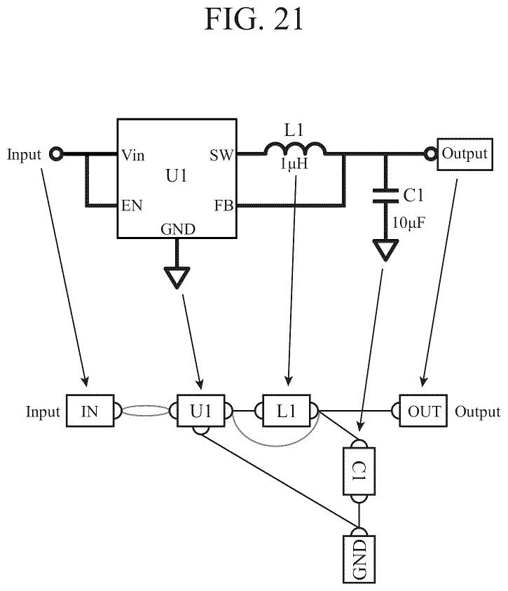

FIG. 21 is a schematic diagram illustrating an example (2) of an electric circuit and a graph network in the second embodiment. As illustrated in the first embodiment, the graph illustrated in FIG. 21 is configured by providing the input terminal, the output terminal, and the ground terminal in the component name list. It can be seen that the circuit diagram has a structure similar to that in FIG. 20.

However, it can be seen that the line between “IN” and “U1” in the lower graph of FIG. 21 is a multiple side, and further, in the line from “U1” to “OUT”, a line passing through L1 and a line not passing through L1 exist, and the circuit diagram and the graph are not the same. In many cases where the graph is utilized, some information deterioration is allowed, and thus the method of the first embodiment is more effective than the conventional method. However, the circuit diagram is not completely reversibly converted from the graph.

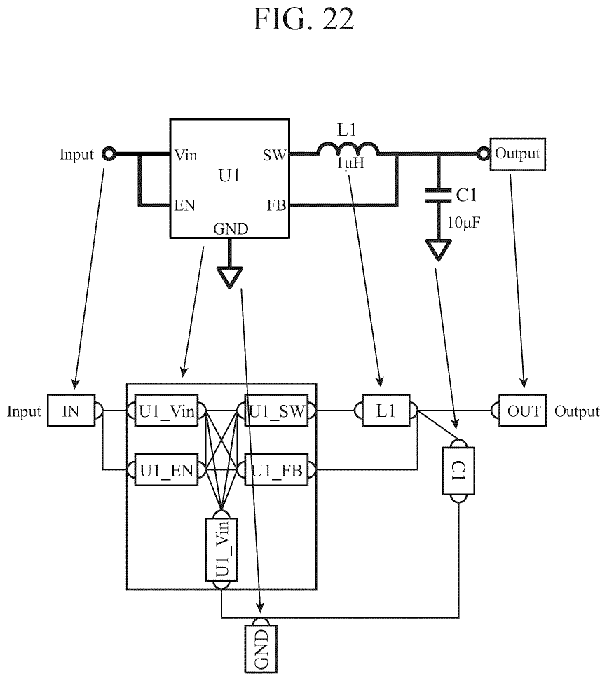

FIG. 22 is a schematic diagram illustrating an example (3) of an electric circuit and a graph network according to the second embodiment. When the processing unit 12A disassembles a component having three or more terminals in the electric circuit into two-terminal components, the electric circuit has a structure in which the two-terminal components are connected to each wiring as illustrated in FIG. 22. That is, the two-terminal components in the electric circuit are all connected to each other, and thus the graph and the circuit diagram can be reversibly converted.

Disassembling the components as described above has an advantage that the graph and the circuit diagram can be reversibly converted, but it is necessary to consider wiring connecting the disassembled components. That is, since necessary information or a calculation amount increases as the number of wirings connecting the disassembled components increases, it is not necessarily excellent as compared with the first embodiment. Thus, it is desirable to select and use the information processing method according to the first embodiment or the information processing method according to the second embodiment in accordance with the inference accuracy required for the graph neural network or the allowable calculation amount.

Also in the second embodiment, as long as a self-loop or multiple sides are not generated, the processing unit 12A may remove a decomposed node and a wiring connected to the node. For example, in a case where it can be determined that there is no information regarding the multiple sides or the self-loop itself, the node and the wiring connected to the node may be removed. By removing in this way, not only the processing can be speeded up, but also the inference accuracy of the graph neural network can be improved since unnecessary information is not included.

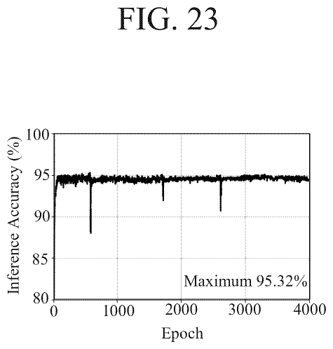

FIG. 23 is a graph illustrating an example of a calculation result of inference accuracy by the information processing device 1A according to the second embodiment, and illustrates a result in a case where components of three or more terminals are disassembled.

In order to compare with the result illustrated in FIG. 15 in which the inference accuracy is the highest, only the identification number of the component is assigned to the node, and only the connection information between the identification numbers is input to the edge. Similarly to FIG. 15, the correct answer data is a classification problem for classifying nine circuits by type.

The training including the circuit constants was performed using the same graph neural network as the graph neural network that obtained the result illustrated in FIG. 15, and inference of the classification was performed using the graph neural network after training. Thus, the inference accuracy is 95.32%, which is 3.58% lower than the result illustrated in FIG. 15. This is because training is performed including the relationship between the two-terminal components obtained by the decomposition, and it is expected that the number of training data is small in order to determine these unknowns. As described above, the information processing method in the second embodiment is a method suitable for a case where high lossless transformation between the netlist and the graph is required, but the information processing method in the first embodiment may be superior in some cases.

On the other hand, when correct information is obtained in advance by circuit simulation or the like, the weight of the calculated edge may not be trained and the update may be stopped in the training of the graph neural network. In this case, it is possible to improve the inference accuracy of the graph neural network even if the processing of disassembling the component having three or more terminals into the two-terminal component is performed.

In this manner, it is desirable to use the information processing method according to the first embodiment and the information processing method according to the second embodiment depending on the data or purpose that can be prepared.

In the above example, the correct answer data is used as the type of circuit, but the frequency characteristic of the output waveform or the like obtained by the circuit simulator may be used as the training data. In this case, it is possible to create teacher data as much as necessary for training by utilizing the circuit simulator.

In addition, if the correct answer data is changed by predicting a signal waveform of specific wiring in the circuit, predicting the area of the eye pattern of the signal waveform, predicting the heat generation of a specific portion of the circuit, predicting the cost of components necessary for constituting the circuit, or predicting the frequency characteristic of electromagnetic noise coming out to the input terminal without limiting to the output waveform, it is possible to freely train the graph neural network according to the purpose.

In addition, by creating and using attribute information data of an edge in combination with circuit simulation, calculations similar to the above can be performed even in a directed graph including the directivity of the current.

It is also possible to impart a frequency characteristic of a voltage to a node or to impart a frequency characteristic of a current to an edge. However, as described in Modification 3, when the frequency data is input to the column of attribute information of the node or the edge of the graph neural network by one frequency, a large matrix is obtained, and a large calculation time and a large calculation amount are required for training. In such a case, while a high-performance computer having a large memory may be prepared to train, for example, by training information obtained by converting frequency characteristics into a vector amount by graph embedding, even if input data has a large matrix including frequency characteristics in a large-scale circuit, a calculation amount thereof can be reduced, and it is possible to train a graph neural network without using a high-performance computer.

In addition, in an electric circuit having a plurality of components connected in parallel to one wiring, the number of combinations of components increases even in the information processing method according to the second embodiment described above. That is, when the electric circuit has a plurality of components connected in parallel to one wiring, the combination of the components corresponding to each other in the combination list increases in proportion to about the square of the number of components connected in parallel to the wiring. For this reason, the calculation amount required for searching the current loop exponentially increases, and the search time also increases.

Accordingly, the information processing device 1A may create a combination list including wiring names and component names so as to suppress an increase in the number of combinations of component names for a large-scale circuit in which a plurality of components is connected in parallel to one wiring. For example, similarly to the first embodiment, the processing unit 12A creates a component name list updated by adding component names indicating a ground terminal, an input terminal, and an output terminal, and creates a wiring name list updated by removing wiring names indicating a ground wiring, an input wiring, and an output wiring. Then, as described above, the processing unit 12A adds a component name indicating a two-terminal component to the updated component name list by regarding components connected to three or more wirings as two-terminal components of the same number as the number of wirings, and removes a component name indicating a component before being regarded as a two-terminal component from the updated component name list. Furthermore, the processing unit 12A defines a connection relationship in which three or more wirings are connected to one terminal of the two-terminal component and the other terminal of the two-terminal component is connected by a new wiring, and adds a wiring name indicating the new wiring to the updated wiring name list. Thereafter, the processing unit 12A extracts a component name corresponding to a wiring name in the updated wiring name list from the updated component name list, creates a combination list including the extracted component name and the wiring name corresponding thereto, and outputs the updated component name list and combination list. That is, the combination list includes the component name corresponding to the wiring name in the updated wiring name list and the wiring name corresponding thereto. The graph network converted from the list information including the combination list has characteristics that the component name and the wiring name are represented by nodes, and as illustrated in FIG. 10, a node adjacent to a node having any component name is a node of a wiring name. Thus, the number of combinations can be set to a number proportional to the first power of the number of components.

As described above, in the information processing device 1A according to the second embodiment, the processing unit 12A adds, to the updated component name list, a component name indicating a two-terminal component by regarding a component connected to three or more wirings as the number of two-terminal components equal to the number of wirings by using a component name list updated by adding component names indicating a ground terminal, an input terminal, and an output terminal and a wiring name list updated by removing wiring names indicating a ground wiring, an input wiring, and an output wiring, removes a component name indicating a component before being regarded as the two-terminal component from the updated component name list, connects the three or more wirings to one terminal of the two-terminal component, connects other terminals of the two-terminal component by a new wiring, adds a wiring name indicating the new wiring to the updated wiring name list, extracts a component name corresponding to a wiring name in the updated wiring name list from the updated component name list, creates the combination list including the extracted component name, and outputs the updated component name list and the combination list.

In this manner, the information processing device 1A can provide list information in which information deterioration that occurs when an electric circuit is converted into a graph network can be suppressed. Further, by defining the two-terminal component, it is possible to prevent a self-loop or multiple sides, and it is possible to suppress information deterioration that occurs when the electric circuit is converted into the graph network and the graph network is converted into the electric circuit.

In the information processing device 1A according to the second embodiment, the processing unit 12A creates a component name list updated by adding component names indicating a ground terminal, an input terminal, and an output terminal and a wiring name list updated by removing wiring names indicating a ground wiring, an input wiring, and an output wiring, adds a component name indicating a two-terminal component to the updated component name list by regarding a component connected to three or more wirings as a two-terminal component whose number is the same as the number of wirings, and removes a component name indicating a component before being regarded as a two-terminal component from the updated component name list. A connection relationship in which three or more wirings are connected to one terminal of a two-terminal component, and another terminal of the two-terminal component is connected by a new wiring is defined, a wiring name indicating new wiring is added to an updated wiring name list, a component name corresponding to a wiring name in the updated wiring name list is extracted from the updated component name list, a combination list including the extracted component name and the wiring name corresponding thereto is created, and the updated component name list and combination list are output. In this manner, the information processing device 1A can provide list information in which information deterioration that occurs when an electric circuit is converted into a graph network can be suppressed. Furthermore, since the information processing device 1A can suppress an increase in the number of combinations of components, the calculation amount and the calculation time required for the processing of the graph neural network using the list information including the combination list can be reduced.

In the information processing device 1A according to the second embodiment, the processing unit 12A outputs an updated component name list and combination list in which component names are replaced with unique identification numbers for each component feature. Thus, the information processing device 1A can reduce the amount of information by expressing the list information with a numerical value, and can prevent information deterioration that occurs when the list information is converted into the graph network.

An information processing method according to the second embodiment includes executing, by the information processing device 1A, adding, to the updated component name list, component names indicating a two-terminal component by regarding a component connected to three or more wirings as a number of two-terminal components equal to a number of wirings, removing a component name indicating a component before being regarded as the two-terminal component from the updated component name list, connecting each of the three or more wirings to one terminal of the two-terminal component, connecting other terminals of the two-terminal component by a new wiring, and adding a wiring name indicating the new wiring to the updated wiring name list, extracting a component name corresponding to a wiring name in the updated wiring name list from the updated component name list, and creating the combination list including the extracted component name, and outputting the updated component name list and the combination list. In this manner, by defining the two-terminal component, it is possible to prevent a self-loop or multiple sides, and it is possible to prevent information deterioration at the time of conversion from the electric circuit to the graph network and conversion from the graph network to the electric circuit.

In the information processing device 1A according to the second embodiment, the processing unit 12A removes a node from the two-terminal component as long as a self-loop or multiple sides are not generated in the wiring connecting the two-terminal components. Thus, the information processing device 1A can provide list information in which information deterioration at the time of creating graph information of an electric circuit can be suppressed.

An information processing method according to the second embodiment includes executing, by the information processing device 1A, creating a component name list that is updated by adding component names indicating a ground terminal, an input terminal, and an output terminal, and a wiring name list that is updated by removing wiring names indicating a ground wiring, an input wiring, and an output wiring, adding, to the updated component name list, component names indicating a two-terminal component by regarding a component connected to three or more wirings as a number of two-terminal components equal to a number of wirings, removing a component name indicating a component before being regarded as the two-terminal component from the updated component name list, connecting each of the three or more wirings to one terminal of the two-terminal component, connecting other terminals of the two-terminal component by a new wiring, and adding a wiring name indicating the new wiring to the updated wiring name list, extracting a component name corresponding to a wiring name in the updated wiring name list from component names in the updated component name list, creating the combination list including the extracted component name, and outputting the updated component name list and the combination list.

In this manner, it is possible to provide list information in which information deterioration that occurs when an electric circuit is converted into a graph network can be suppressed.

Furthermore, by defining the two-terminal component, it is possible to prevent a self-loop or multiple sides, and it is possible to suppress information deterioration that occurs when the electric circuit is converted into the graph network and the graph network is converted into the electric circuit.

The information processing method according to the second embodiment includes executing, by the information processing device 1A, extracting a component name corresponding to a wiring name in the updated wiring name list from component names in the updated component name list, creating a combination list including the extracted component name and the wiring name corresponding thereto, and outputting the updated component name list and the combination list. In this manner, it is possible to provide list information in which information deterioration that occurs when an electric circuit is converted into a graph network can be suppressed. Furthermore, since an increase in the number of combinations of components can be suppressed, an increase in the calculation amount and the calculation time required for the processing of the graph neural network using the list information including the combination list can be reduced.

Note that combinations of the individual embodiments, modifications of any components of the individual embodiments, or omissions of any components in the individual embodiments are possible.

### INDUSTRIAL APPLICABILITY

An information processing device according to the present disclosure can be used for designing a circuit using circuit design CAD and board design CAD, for example.

### REFERENCE SIGNS LIST

1, 1A: information processing device, 11: acquisition unit, 12, 12A: processing unit, 100: input interface, 101: output interface, 102: processing circuit, 103: processor, 104: memory

1. An information processing device comprising:
a processor; and
a memory storing a program, upon executed by the processor, to perform a process:
to acquire a netlist of an electric circuit; and
to extract a component name list and a wiring name list from the netlist, and create a component name list that is updated by adding component names indicating a ground terminal, an input terminal, and an output terminal, a wiring name list that is updated by removing wiring names indicating a ground wiring, an input wiring, and an output wiring, and a combination list including an extracted component name obtained by extracting a component name corresponding to a wiring name in the updated wiring name list from the component names in the updated component name list, and output the updated component name list and the combination list.

2. The information processing device according to claim 1, wherein
the process
adds, to the updated component name list, component names indicating a two-terminal component by regarding a component connected to three or more wirings as a same number of two-terminal components as a number of wirings,
removes a component name indicating a component before being regarded as the two-terminal component from the updated component name list,
connects each of the three or more wirings to one terminal of the two-terminal component,
connects other terminals of the two-terminal component by a new wiring,
adds a wiring name indicating the new wiring to the updated wiring name list,
extracts a component name corresponding to a wiring name in the updated wiring name list from the updated component name list, and
creates the combination list including the extracted component name, and outputs the updated component name list and the combination list.

3. An information processing device comprising:
a processor; and
a memory storing a program, upon executed by the processor, to perform a process:
to acquire a netlist of an electric circuit; and
to extract a component name list and a wiring name list from the netlist, and create a component name list that is updated by adding component names indicating a ground terminal, an input terminal, and an output terminal, a wiring name list that is updated by removing wiring names indicating a ground wiring, an input wiring, and an output wiring, and a combination list including an extracted component name obtained by extracting a component name corresponding to a wiring name in the updated wiring name list from the component names in the updated component name list and a wiring name corresponding to the extracted component name, and output the updated component name list and the combination list.

4. The information processing device according to claim 3, wherein
the process
adds, to the updated component name list, component names indicating a two-terminal component by regarding a component connected to three or more wirings as a same number of two-terminal components as a number of wirings,
removes a component name indicating a component before being regarded as the two-terminal component from the updated component name list,
connects each of the three or more wirings to one terminal of the two-terminal component,
connects other terminals of the two-terminal component by a new wiring,
adds a wiring name indicating the new wiring to the updated wiring name list,
extracts a component name corresponding to a wiring name in the updated wiring name list from the updated component name list,
creates the combination list including the extracted component name and the wiring name corresponding to the extracted component name, and
outputs the updated component name list and the combination list.

5. The information processing device according to claim 1, wherein
the process outputs the updated component name list and the combination list in which a component name is replaced with a unique identification number common to each of features of components.

6. The information processing device according to claim 5, wherein
the process defines the unique identification number common to each of types of components.

7. The information processing device according to claim 5, wherein
the process defines the unique identification number common to each of model numbers of components.

8. The information processing device according to claim 5, wherein
the process replaces a component name in the updated component name list with a row or a column of a feature amount matrix obtained by one-hot expression of a feature of the component.

9. The information processing device according to claim 8, wherein
the process replaces an element corresponding to a passive circuit in the feature amount matrix with a function value calculated by substituting a circuit constant of a component into a function including a logarithm.

10. The information processing device according to claim 9, wherein
the process performs both or one of normalization and standardization on the function value.

11. The information processing device according to claim 2, wherein
the process removes a node from the two-terminal component as long as a self-loop or multiple sides are not generated in the wiring connecting the two-terminal components.

12. The information processing device according to claim 1, wherein
the component name list is a node in a graph network,
the wiring name list is an edge in the graph network, and
the combination list is an adjacency matrix in the graph network.

13. The information processing device according to claim 12, wherein
the process sets a combination of a node and an edge as input data of a graph neural network.

14. An information processing method comprising:
acquiring a netlist of an electric circuit;
extracting a component name list and a wiring name list from the netlist;
creating a component name list that is updated by adding component names indicating a ground terminal, an input terminal, and an output terminal;
creating a wiring name list that is updated by removing wiring names indicating a ground wiring, an input wiring, and an output wiring;
extracting a component name corresponding to a wiring name in the updated wiring name list from the component names in the updated component name list, and creating a combination list including the extracted component name; and
outputting the updated component name list and the combination list.
